(19) United States
(12) Patent Application Publication
(10) Pub. No.: US 2012/0261651 A1
(43) Pub. Date: Oct. 18, 2012

(54) ORGANIC ELECTROLUMINESCENT ELEMENT AND NOVEL ALCOHOL-SOLUBLE PHOSPHORESCENT MATERIAL

(76) Inventors: Mitsuharu Noto, Fukuoka (JP); Yumi Sakai, Fukuoka (JP); Izumi Kakinoki, Fukuoka (JP); Yasuyuki Goto, Fukuoka (JP)

(21) Appl. No.: 13/499,016

(22) PCT Filed: Aug. 17, 2010
(86) PCT No.: PCT/JP2010/005087

§ 371 Date: May 21, 2012

(30) Foreign Application Priority Data
Aug. 18, 2009 (JP) 2009-188846

(51) Int. Cl. H01L 51/54; C07F 17/00

(52) U.S. Cl. 257/40; 546/4; 548/103; 257/E51.026

(57) ABSTRACT

Object of the present invention is to provide an organic electroluminescent element having an emissive layer that may be formed by wet process in the fabrication of the organic electroluminescence device with multi-layer structure and has excellent electron-injection property, electron-transfer property, durability and luminescent efficiency and a novel alcohol-soluble organic phosphorescent material that may be preferably applicable to the fabrication of the same. An organic electroluminescent element 1 has a plurality of laminated organic layers 4, 5, 6 sandwiched between anode 3 and cathode 7. A hole transport layer 5 composed of organic compounds insoluble in alcohol solvent and an emissive layer 6 formed by a wet process so that it contacts with the hole transport layer 5 on the side facing with the cathode 7 contains host materials consisting of one or more phosphine oxide derivatives soluble in alcohol solvent and guest materials soluble in alcohol solvent which can be excited electrically to emit light.

### BACKGROUND OF THE INVENTION

1. Field of the Invention

The present invention relates to an organic electroluminescent element and novel alcohol-soluble phosphorescent material. Particularly, the present invention relates to an organic electroluminescent element having an emissive layer that may be formed by wet process in the fabrication of the organic electroluminescence device with multi-layer structure and has excellent electron-injection property, electron-transfer property, durability and luminescent efficiency and to a novel alcohol-soluble organic phosphorescent material that may be preferably applicable to the fabrication of the same.

2. Description of the Related Art

An organic electroluminescent element in which an emissive organic layer (organic electroluminescent layer) is situated between anode and cathode (hereinafter abbreviated as “organic EL element”) has advantages that it may be operated at DC low voltage and has higher luminance and emission efficiency compared with an inorganic EL element and attracts attention as a display device of next generation. Recently, a full-color display panel based on the organic EL element has been put on the market and research and development has been intensively conducted aiming to improvement in display size and durability and the like.

An organic EL element is an electroluminescent element in which organic compound is electrically excited by recombination of injected holes and electrons to emit light. Since high luminance of organic multilayer thin-film element was reported at Eastman Kodak by C. W. Tang et al. (C. W. Tang, S. A. VanSlyke, “Organic electroluminescent diodes”, Applied Physics Letters, Vol. 51, No. 12, 1987, 913-915), a number of researches and developments on the organic EL element have been carried by several companies and research institutes. In a typical organic EL element developed by Eastman Kodak, diamine compound as a hole transport material, tris (8-quinolilate) aluminum (III) as a luminescent material, and Mg:Al as a cathode are laminated successively on ITO (indium tin oxide) glass substrate as a transparent anode, in which green luminescent of ca. 1000 cd/cm² is observed at driving voltage of ca. 10 V. The laminated organic EL elements that have been researched and put in practical use are based on the element of Eastman Kodak.

The organic electroluminescent elements are classified into polymer organic EL element and small-molecule organic EL element in terms of its constituent materials. The former is produced by wet process and the latter is produced by vapor deposition or wet process. Because of the difficulty in balancing hole transfer property with electron transfer property of the conductive polymer material used for the production of the polymer organic EL element, the laminated small-molecule organic EL element in which the functions of electron transfer, hole transfer and emission are separated is becoming mainstream of the organic EL elements.

In the laminate small-molecule organic EL element, the performances of electron transport layer, the electron injection layer and hole transport layer situated between an organic electroluminescent layer and an electrode greatly influence the property of the element. Therefore, the research and development for improving these materials has been intensively conducted and a number of the results of the improvement research of the electron transport layer and the electron injection layer are reported.

For example, Japanese published unexamined application No. 2005-63910 discloses the improvement of the electron injection layer by doping metal compound in the electron injection layer by means of co-evaporation of the metal compound containing alkali metal with low work function (electronegativity) and electron-conducting organic compound.

Japanese published unexamined application No. 2002-63989 discloses the use of phosphine oxide compound as the electron transport material. Japanese published unexamined application No. 2002-352961 discloses the doping of alkali metal to the organic compound having coordination site constituting the electron transport layer.

### SUMMARY OF THE INVENTION

However, the electron injection layer, the electron transport material and the electron transport layer according to the aforementioned patent documents have been developed in order to lower the operation voltage and to improve the luminescent efficiency rather than to enable the production of multilayer structure by wet process and to improve durability. Moreover, production of the electron transport layer and the electron injection layer according to the aforementioned inventions by means of vacuum vapor deposition method requires large-scale facility and has the difficulty in precisely adjusting the deposition rates in the simultaneous deposition of more than two materials, which leads to a decrease in the productivity.

The production methods of the layered low-molecule organic EL element by wet process are classified into two categories: one is a method in which the upper layer is formed after the lower layer formed is insolubilized by heat or photo-induced cross linking or polymerization, and the other is a method in which the upper and lower layers are formed using the material with markedly different solubility. In the former method, while a wide variety of materials may be chosen, removal of an initiator and unreacted material is difficult after the cross linking or the polymerization, which causes the problem in durability. On the other hand, in the latter method, while the choice of the materials is difficult, the element having higher purity and durability may be produced comparing with the former method because no chemical reaction such as the cross linking and the polymerization is not required. As mentioned above, the method using the difference in the solubility of the material for each layer is preferred for the production of the layered low-molecule organic EL element in spite of the difficulty in choosing the materials. One of the factors that make the lamination using the different in the solubility of constituent material of each layer difficult is that most conducting polymers and spin-coatable organic semiconductors are soluble in solvents with relatively high solubilizing ability such as toluene, chloroform and tetrahydrofuran. Therefore, when a spin-coating of a n-type conductive polymer is carried out after forming a hole transport layer of p-type conductive polymer using similar solvents, etching of the underlying hole carrier polymer layer occurs, which makes difficult to form a lamination structure with flat and defect-free p-n interface. Especially, in an ink-jet process in which solvent is removed by natural drying, strong etching of the hole transport layer and the luminescent layer takes place because the solvent stays longer, which makes the achievement of the sufficient properties for practical purposes very difficult.

In terms of improving the properties by using materials optimized for functions of the electron transfer, the hole transfer and the luminescent, it is preferred to increase the number of layers to be laminated between the anode and the cathode by separating each function. However, increasing number of layers to be laminated may lead to increase in number of processes and tact time required for the production and performance degradation due to the etching of the underlying layer by the solvent.

Under these circumstances, the object of the present invention is to provide an organic electroluminescent element having an emissive layer that may be formed by wet process in the fabrication of the organic electroluminescence device with multi-layer structure and has excellent electron-injection property, electron-transfer property, durability and luminescent efficiency and to a novel alcohol-soluble organic phosphorescent material that may be preferably applicable to the fabrication of the same.

First aspect of the present invention that meets the aforementioned purpose provides an organic electroluminescent element having a plurality of laminated organic layers sandwiched between anode and cathode, wherein the plurality of laminated organic layers comprising:

a hole transport layer composed of organic compounds insoluble in alcohol solvent and;

an emissive layer formed by a wet process so that it contacts with the hole transport layer on the side facing with the cathode, wherein the emissive layer contains host materials consisting of one or more phosphine oxide derivatives soluble in alcohol solvent and guest materials consisting of one or more organic compounds and/or organic metal compounds soluble in alcohol solvent having phosphine oxide moiety not coordinating to transition metals or ions thereof which can be excited electrically by recombination of injected electrons and holes to emit light to solve the aforementioned problems.

Since both of the host and guest materials in the emissive layer are soluble in alcohol solvent, the emissive layer may be formed by means of wet process using the alcohol solvent. In addition, since the hole transport layer is insoluble in the alcohol solvent, the organic electroluminescent element may be produced without suffering from defect and performance deterioration because no etching or swelling of the hole transport layer does not take place even when the emissive layer is formed after the hole transport layer has been formed. Moreover, since the phosphine oxide derivatives used as host materials have electron withdrawing phosphine oxide (P═O) group, the emissive layer itself has excellent electron transfer property and electron injection property. Therefore, good property required for the organic electroluminescent element may be achieved without otherwise forming electron transport layer separately, which enables the reduction of production steps as well as the tact time required for the production.

In the first aspect of the present invention, the guest material preferably has one or more phosphine oxide moieties that do not coordinate to transition metal element or ion. Introduction of electron withdrawing phosphine oxide (P═O) moieties to the phosphine oxide derivative used as the guest material may lead to the improvement in the electron transfer property and electron injection property of the emissive layer.

In the first aspect of the present invention, the emissive layer preferably further comprises one or more metal salt or metal compounds of the metal with the electronegativity of 1.6 or less.

Coordination of the metal (element or ion) with low electronegativity (1.6 or less) to electron withdrawing phosphine oxide moiety may lead to the improvement in the electron transfer property and electron injection property of the phosphine oxide derivative constituting the host material and durability.

In the first aspect of the present invention, the phosphine oxide derivative constituting the host material may be represented by the general Formula (1) shown below:

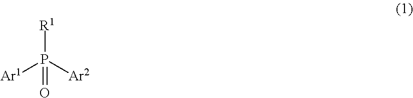

wherein

R¹ in Formula (1) is a group having one or more aryl and/or heteroaryl groups, which may have a phosphine oxide group represented by Formula (2) shown below on any carbon atoms;

Ar¹ and Ar² are aryl groups which may have one or more substituents independently of each other, where Ar¹ and Ar² may bind to form a heterocycle containing phosphorous atom; and

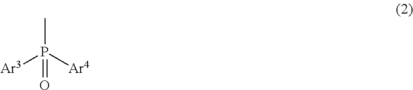

Ar³ and Ar⁴ in Formula (2) are aryl groups that may have one or more substituents independently of each other, where Ar³ and Ar⁴ may bind to form a heterocycle containing phosphorous atom.

Here, the phosphine oxide derivatives represented by Formula (1) are preferably one or more phosphine oxide derivatives selected from the group consisting of the compounds represented by the Formulae A to Q shown below.

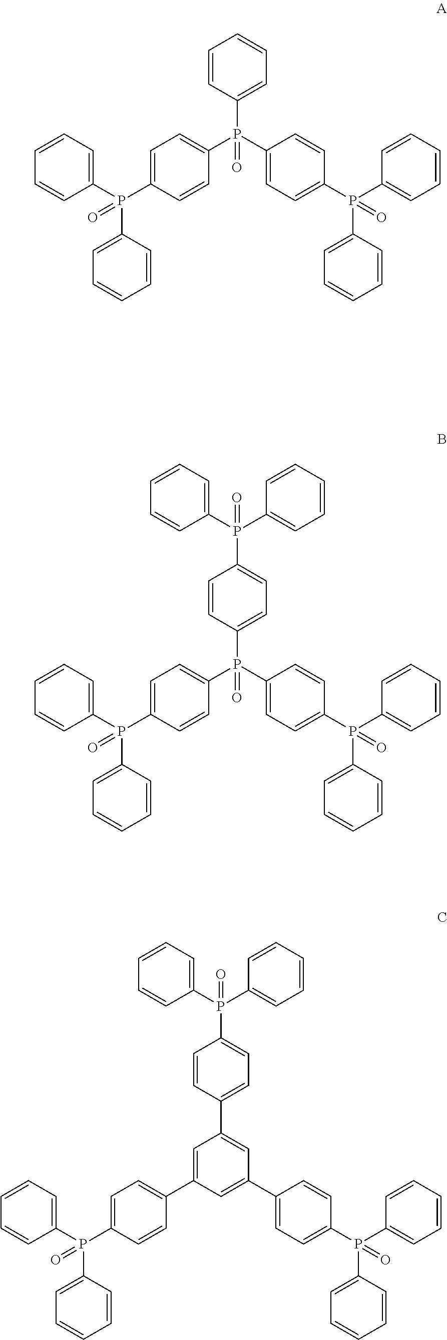

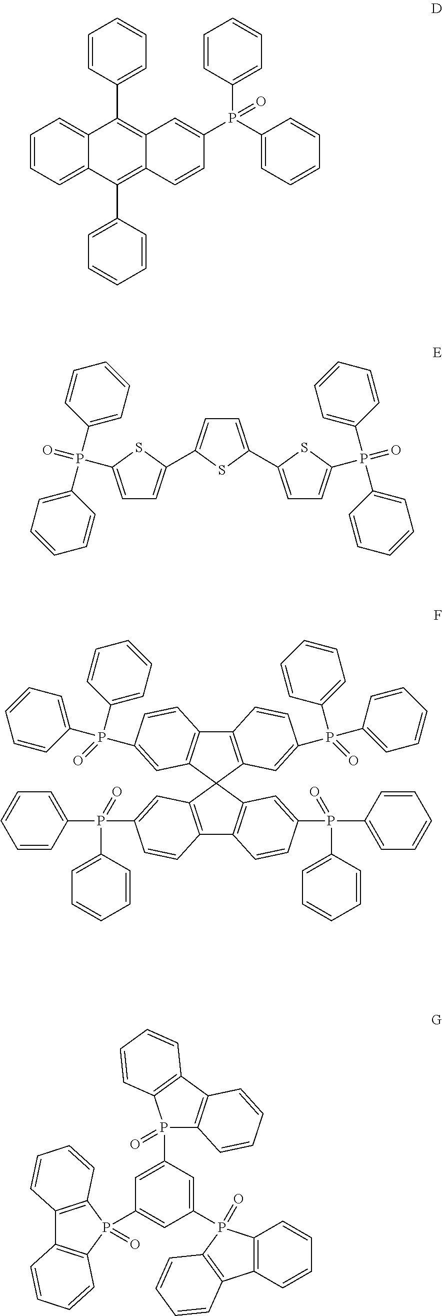

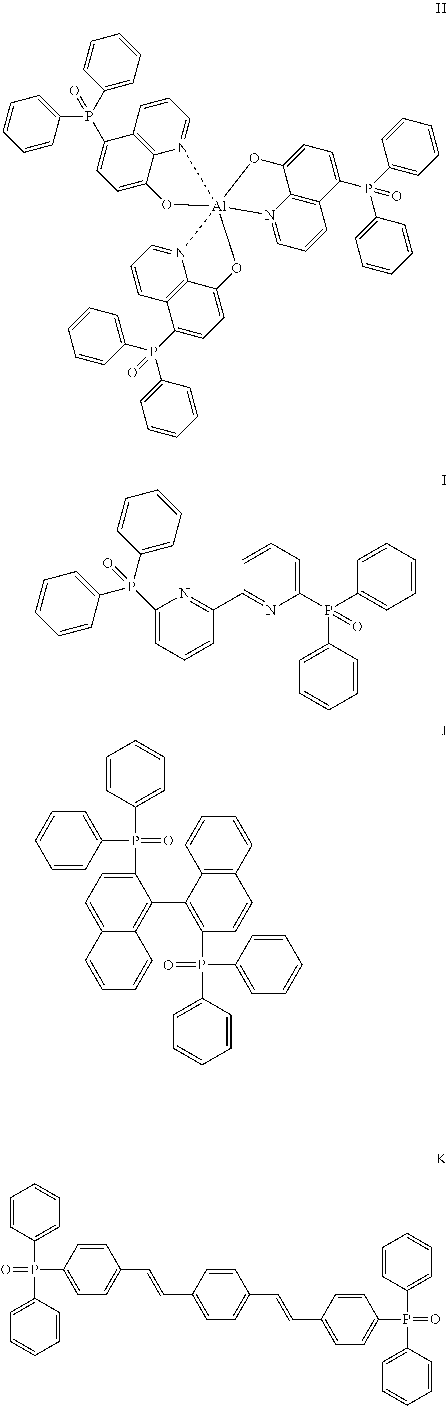

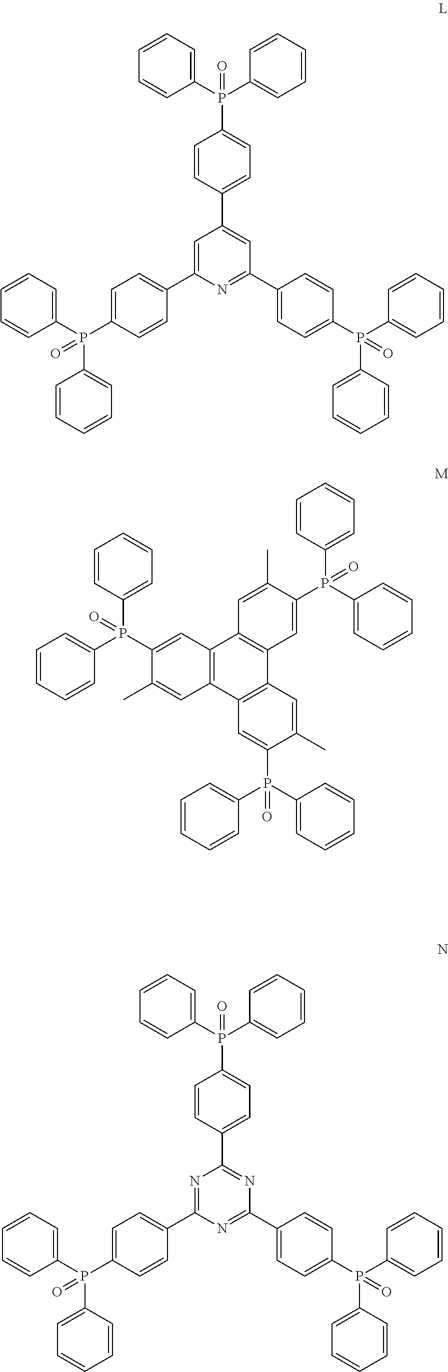

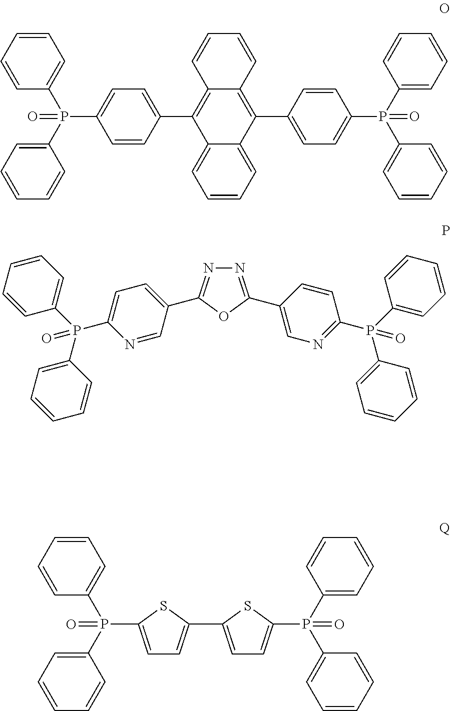

In the first aspect of the present invention, the organic compounds and/or organic metal compounds constituting the guest material may be represented by general Formula (3) shown below;

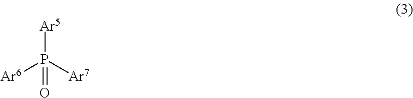

Ar⁵, Ar⁶ and Ar⁷ in Formula (3) are aryl or heteroaryl groups that may have one or more substituents independently of each other, and at least one of Ar⁵, Ar⁶ and Ar⁷ are luminescence aromatic moieties that can be excited electrically by recombination of injected electrons and holes to emit light.

Here, the organic compounds and/or organic metal compounds represented by general Formula (3) is preferably the iridium complex represented by Formula (3)′, and more preferably the iridium complex represented by any one of Formula (4) to (15) shown below and further more preferably, the iridium complex represented by Formula (4)′ shown below.

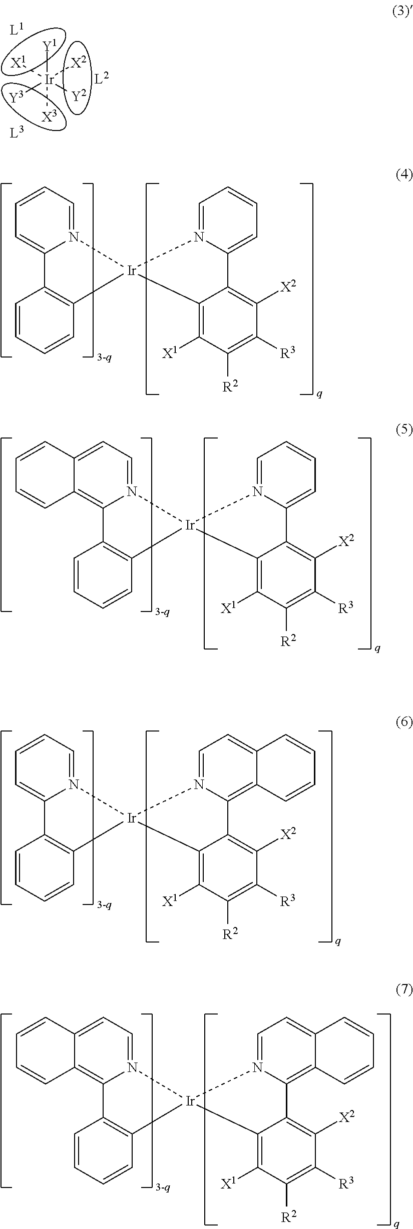

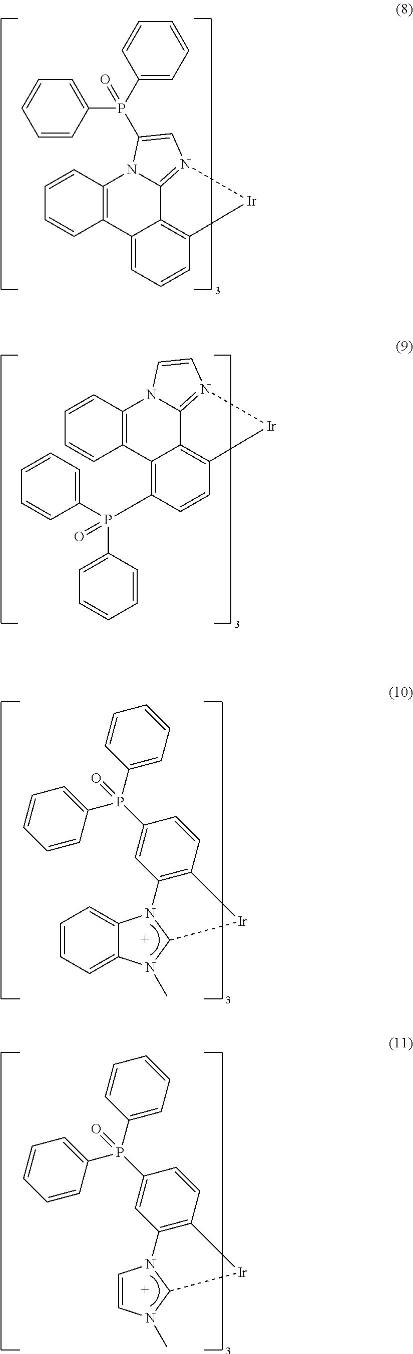

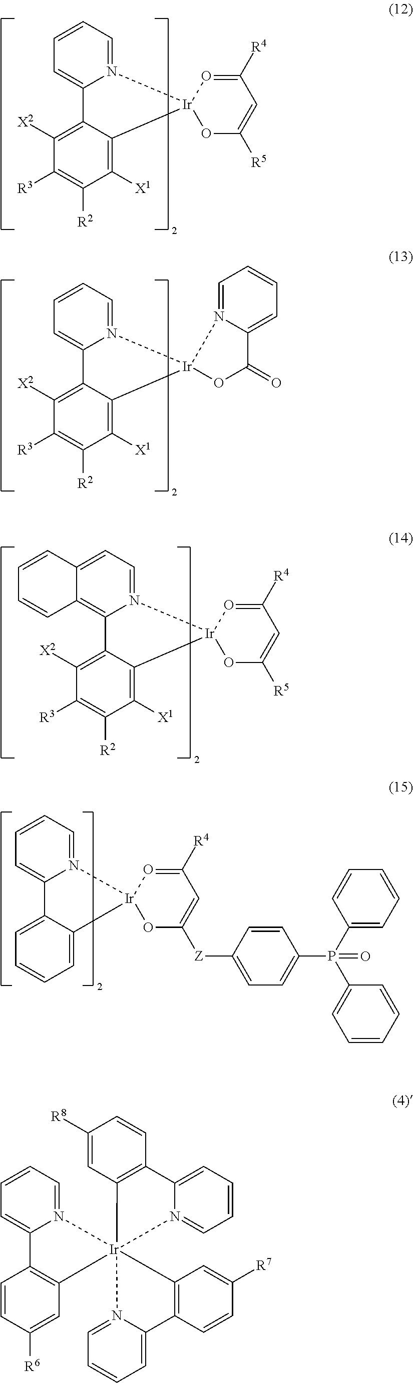

L¹, L² and L³ in Formula (3)′ are bidendate ligands, X¹ and Y¹, X² and Y², and X³ and Y³ are coordinating atoms of L¹, L² and L³, respectively selected from the group consisting of carbon, oxygen and nitrogen atoms and at least one of L¹, L² and L³ have phosphine oxide group represented by Formula (2) shown above.

The one of R² and R³ in Formula (4) to (15) is hydrogen atom or phosphine oxide group represented by Formula (2) shown below, the other of R² and R³, X¹ and X² are selected from the group consisting of hydrogen and fluorine atoms independently of each other, q is an integer of 1, 2 or 3, R⁴ and R⁵ are groups selected from the group consisting of linear or branched alkyl groups having 1 to 12 carbon atoms, linear or branched fluoroalkyl groups having 1 to 12 carbon atoms, aryl groups and heteroaryl groups, and Z is direct bond or linear alkylene group having 1 to 12 carbon atoms.

R⁶, R⁷ and R⁸ in Formula (4)′ are hydrogen atom or phosphine oxide group represented by Formula (2) shown above and at least one of R⁶, R⁷ and R⁸ are phosphine oxide group represented by Formula (2) shown above.

The second aspect of the present invention provides an alcohol-soluble phosphorescent material represented by Formula (3)′ shown above to solve the aforementioned problems.

In the second aspect of the present invention, the iridium complex represented by Formula (3)′ is preferably the iridium complex represented by any one of Formula (4) to (15) shown above and more preferably, the iridium complex represented by Formula (4)′ shown above.

The iridium complex represented by the Formula (3)′, preferably any one of Formula (4) to (15), more preferably Formula (4)′ may be excited electrically to emit phosphorescence via triplet state with high quantum yield. Since the iridium complex represented by any one of the aforementioned formulae is soluble in alcohol solvent and have bulky phosphine oxide moiety, they hardly aggregate in the alcohol solution and in the emissive layer. Therefore, they have high luminescent efficiency without suffering from the deterioration of the luminescent efficiency due to the concentration quenching.

The present invention provides an organic electroluminescent element having an emissive layer that may be formed by wet process in the fabrication of the organic electroluminescence device with multi-layer structure and has excellent electron-injection property, electron-transfer property, durability and luminescent efficiency and a novel alcohol-soluble organic phosphorescent material that may be preferably applicable to the fabrication of the same. By the use of the alcohol-soluble phosphorescent material of the present invention, the electron transport layer and the laminated low-molecule organic EL element without using expensive vacuum deposition equipment and complicated setting for co-evaporation of the metal and the organic electron transport material. Hence, production cost of the production of the electron transport layer and the laminated low-molecule organic EL element may be reduced as well as the productivity may be enhanced. By the application of the present invention, the organic electroluminescent element that may be produced at high productivity and low cost and is excellent in luminescent efficiency and durability may be provided.

### BRIEF DESCRIPTION OF THE DRAWINGS

FIG. 1 is a schematic view showing the longitudinal section of the organic electroluminescent element according to an embodiment of the present invention.

### DESCRIPTION OF THE EMBODIMENTS

Hereinafter, embodiments of the present invention will be described to provide better understanding of the present invention.

### (1) Organic Electroluminescent Element

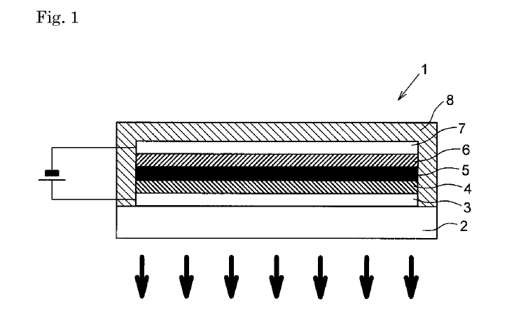

As shown in FIG. 1, the organic electroluminescent element 1 according to the first embodiment of the present invention comprises a plurality of laminated organic layers sandwiched between anode 3 and cathode 7 (comprising a hole injection layer 4, a hole transport layer 5, and an emissive layer 6 laminated in this order from the side of the anode 3). The anode 3 is formed on the transparent substrate 2 and the whole of the laminated organic layers and electrodes are sealed with a sealant 8. The hole transport layer 5 is composed of organic compounds insoluble in alcohol solvent. The emissive layer 6 formed by a wet process so that it contacts with the hole transport layer 5 on the side facing with the cathode 7 contains host materials consisting of one or more phosphine oxide derivatives soluble in alcohol solvent and guest materials (emission center) consisting of one or more organic compounds and/or organic metal compounds soluble in alcohol solvent having phosphine oxide moiety not coordinating to transition metals or ions thereof which can be excited electrically by recombination of injected electrons and holes to emit light.

The substrate 2 provides the physical support of the organic electroluminescent element 1. Since the organic electroluminescent element 1 according to the embodiment of the present invention emits the light from the side of the substrate 2 (bottom-emission type), the substrate 2 and the anode 3 is composed of substantially transparent (colorless transparent, colored transparent or translucent) materials. Examples of the constituent materials of the substrate 2 include resins such as polyethylene telephthalate, polyethylene naphthalate, polypropylene, cycloolefin polymer, polyamide, polyethersulfone and polymethyl methacrylate, polycarbonate and polyacrylate; glasses such as quartz glass and soda glass, which may be used alone or in combination of two or more of these materials.

The average thickness of the substrate 2 is not particularly limited but preferably about 0.1 to 30 mm, more preferably about 0.1 to 10 mm. In the organic electroluminescent element 1 that emits light from the opposite side of the substrate 2 (top-emission type), both of the transparent and opaque materials. The examples of the opaque substrate include ceramics substrate such as alumina substrate; the metal substrate such as stainless steel substrate coated with metal oxide film (insulating film); and opaque plastic substrate.

The anode 3 is an electrode to inject holes to the hole injection layer 4 to be described later. The anode 3 preferably consists of the materials with large work function and good conductivity. Examples of the constituent material of the anode 3 include metal oxides such as ITO (indium tin oxide), IZO (indium zirconium oxide), In₃O₃, SnO₂, Sb—SnO₂, and Al—ZnO; Au, Pt, Ag, Cu or alloys of these metal, which may be used alone or in combination of two or more of these materials can be applied. The average thickness of the anode 3 is not particularly limited but preferably about 10 to 200 nm, more preferably about 50 to 150 nm.

The cathode 7 is an electrode to inject electrons to the emissive layer 6 to be described later and situated on the side of the emissive layer 6 opposite to the hole transport layer 5. The material having small work function is preferably used as the constituent material of the cathode 7. Examples of the conctituent material of the cathode 7 include Li, Mg, Ca, Sr, La, Ce, Er, Eu, Sc, Y, Yb, Ag, Cu, Al, Cs, Rb or the alloys thereof, which may be used alone or in combination of two or more of these materials (for example, in the form of multilayer alloy).

Particularly, when the alloy is used as the constituent material of the cathode 7, the alloy containing stable metal element such as Ag, Al, Cu, in particular MgAg, AlLi, CuLi and the like is preferred. By the use of these alloys as the constituent material of the cathode 7, the electron injection efficiency and stability of the cathode 7 may be improved. The average thickness of the cathode 7 is not particularly limited but preferably about 50 to 10000 nm, more preferably about 80 to 500 nm.

In the top emission type organic EL element, the material having small work function or the alloy containing such material is deposited with a thickness of about 5 to 20 nm so that the deposit film is transparent and the film of conducting material having high transparency such as ITO is deposited with a thickness of about 100 to 500 nm. However, transparency of the cathode 7 is not required because the organic electroluminescent element 1 is bottom emission type.

On the surface of the anode 3, the hole injection layer 4 and the hole transport layer 5 are formed. The hole injection layer 4 has the function of receiving holes injected from the anode 3 and transferring to the hole transport layer 5. The hole transport layer 5 has the function of transferring holes injected from the hole injection layer 4 to the emissive layer 6. The constituent materials of the hole injection layer 4 and the hole transport layer 5 include, for example, metallophthalocyanine or metal-free phthalocyanine such as phthalocyanine, copper phthalocyanine (CuPc) and iron phthalocyanine; polyarylamine, fuluorene-arylamine copolymer, fluorine-bithiophene copolymer, poly(N-vinylcarbazole), polyvinylpyrene, polyvinylanthracene, polythiophene, polyalkylthiophene, polyhexylthiophene, poly(p-phenylenevinylene), polythinylenevinylene, pyrene-formaldehyde resin, ethylcarbazole-formaldehyde resin or derivatives thereof, which may be used alone or combination of 2 or more. But, the constituent material of the hole transport layer 5 should be insoluble in alcohol solvent.

Also, the aforementioned materials may be used as a mixture of other compounds. Examples of the mixture containing polythiophene include poly(3,4-ethylenedioxythiophene/styrenesulfonic acid) (PEDOT/PSS) and the like. For the hole injection layer 4 and the hole transport layer 5, one or more appropriate materials are selected or combined to use in terms of the optimization of the efficiency of hole injection and transfer, prevention of the reabsorption of light from the emissive layer 6 and heat resistance and the like.

For instance, for the hole injection layer 4, the material in which the gap between its hole conduction level (Ev) and the work function of the material used for the anode 3 and has no absorption band in visible region to prevent the reabsorption of the emitted light is preferably employed. For the hole transport layer 5, the material which does not form exciplex or charge transfer complex with the constituent material of the emissive layer 6, having siglet excitation energy larger than exciton energy of the emissive layer 6, larger band gap enaergy and shallow electron conduction level (Ec) is preferably employed to prevent the energy of the exition generated in the luminecent layer 6 from moving and to prevent the electrons from the luminecent layer 6 from being injected. Examples of the material preferably used for the hole injection layer 4 and the hole transport layer 5 include poly(3,4-ethylenedioxythiophene/styrenesulfonic acid) (PEDOT/PSS) and poly(N-vinylcarbazole) (PVK), respectively in case that ITO is used to the anode 3.

In this embodiment, the hole injection 4 and the hole transport layer 5 are formed between the anode 3 and the emissive layer 6 as separate two layers, however, they may be a single layer for injecting holes from the anode 3 and transferring holes to the emissive layer 6 or three or more layers having the same or different compositions with each other.

Avarage thickness of the hole injection layer 4 is noto particularly limited, however, preferably about 10 to 150 nm and more preferably 50 to 100 nm. Avarage thickness of the hole transport layer 5 is noto particularly limited, however, preferably about 10 to 150 nm and more preferably 15 to 50 nm.

On the surface of the hole transport layer 5 opposite to the anode 3, the emissive layer 6 is formed. Electrons are carried (injected) from the cathode 7 directly or through an electron transport layer (not shown in FIG. 1) to the emissive layer 6. Holes are carried (injected) from the hole transport layer 5. In the luminsencent layer 6, recombination of holes and electrons takes place and consuming the energy released at the recombination, excitons form, which release energy (emission) upon returning to ground state (fluorescence or phosphorescence).

The emissive layer 6 comprises:

(I) The host material consisting of one or more phosphine oxide derivatives soluble in alcohol solvent, and

(II) The guest material consisting of one or more organic compounds and/or organic metal compounds having one or more phosphine oxide moieties that do not coordinate to transition metal element or ion, and soluble in alcohol solvent which can be excited electrically by recombination of injected electrons and holes to emit light as constituent materials.

### (I) Host Material

The phosphine oxide derivative represented by Formula (1) shown below is preferably used as the constituent material of the host material.

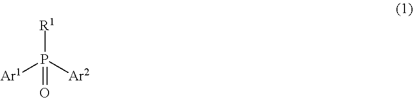

R¹ in Formula (1) is a group having one or more aryl and/or heteroaryl groups, which may have a phosphine oxide group represented by Formula (2) shown below on any carbon atoms.

Ar¹ and Ar² are aryl groups which may have one or more substituents independently of each other, where Ar¹ and Ar² may bind to form a heterocycle containing phosphorous atom; and

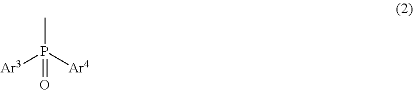

Ar³ and Ar⁴ in Formula (2) are aryl groups that may have one or more substituents independently of each other, where Ar³ and Ar⁴ may bind to form a heterocycle containing phosphorous atom.

The number of carbon atoms of the aryl and heteroaryl group in R¹ is preferably, but not limited to, 2 to 30, and more preferably 2 to 20. More specifically, the examples include monocyclic aromatic hydrocarbon moeties such as phenyl ring; monocyclic heteroaromatic moities such as thiophene ring, triazine ring, furan ring, pyradine ring, pyridine ring, thiazole ring, imidazole ring, and pyrimidine ring; fused polycyclic aromatic hydrocarbon moieties such as naphthalene ring and anthracene ring; fused polycyclic heteroaromatic moieties such as thieno[3,2-b]furan ring; aromatic hydrocarbon ring assemblies such as biphenyl ring and terphenyl ring; heteroaromatic ring assemblies such as bithiophene ring and bifuran ring; fused polyaromatic rings of aromatic hydrocarbon ring and heteroaromatic ring such as acrydine ring, isoquinoline ring, indole ring, carbazole ring, carboline ring, quinoline ring, dibenzofuran ring, cinnoline ring, thionaphthene ring, 1,10-phenanthroline ring, phenothiazine ring, purin ring, benzofuran ring and silole ring. The aryl groups contained in Ar¹ to Ar⁴ are similar to those contained in R¹ mentioned above, and preferably phenyl groups.

Among the phosphine oxide derivatives represented by Formula (1), the phosphine oxide derivatives represented by Formula (16), (17) and (18) shown below are preferably used as the host material.

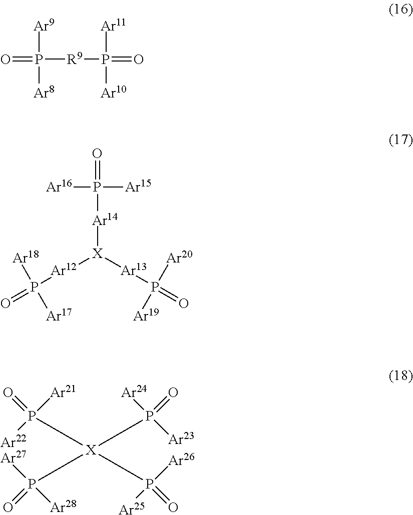

In Formula (16), (17) and (18);

X and R⁹ are groups having one or more aryl and/or heteroaryl groups, which may have one or more substituents,

Ar⁸ to Ar²⁸ are aryl groups which may have one or more substituents independently of each other, and

Ar⁸ and Ar⁹, Ar¹⁰ and Ar¹¹, Ar¹⁵ and Ar¹⁶, Ar¹⁷ and Ar¹⁸, Ar¹⁹ and Ar²⁰, Ar²¹ and Ar²², Ar²³ and Ar²⁴, Ar²⁵ and Ar²⁶, and Ar²⁷ and Ar²⁸ may bind to form a heterocycle containing phosphorous atom, respectively.

The aryl groups contained in X, R⁹ and Ar⁸ to Ar²⁸ are similar to those contained in R¹ mentioned above, and Ar⁸ to Ar²⁸ are preferably phenyl groups.

Examples of the phosphine oxide derivate include the phosphine oxide derivatives represented by the Formula A to Q shown below.

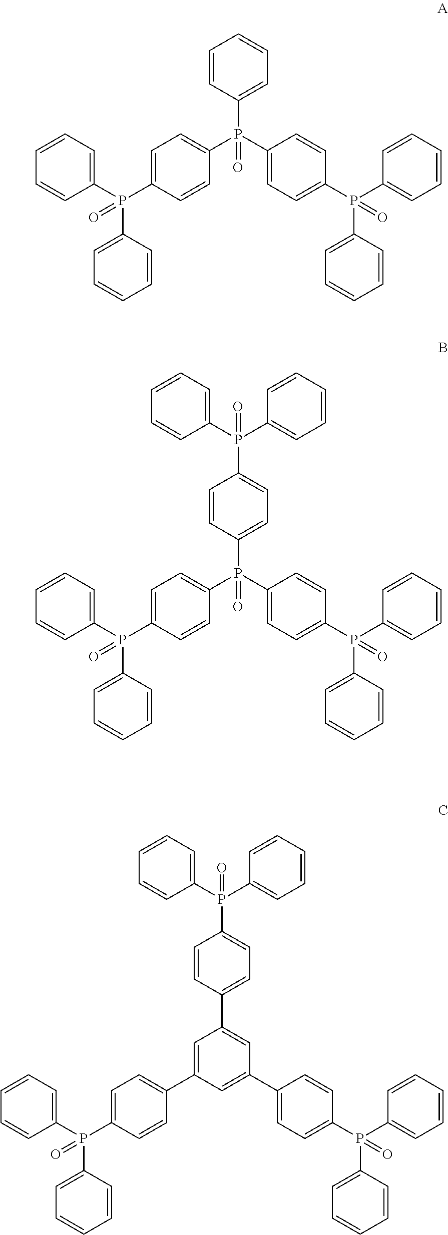

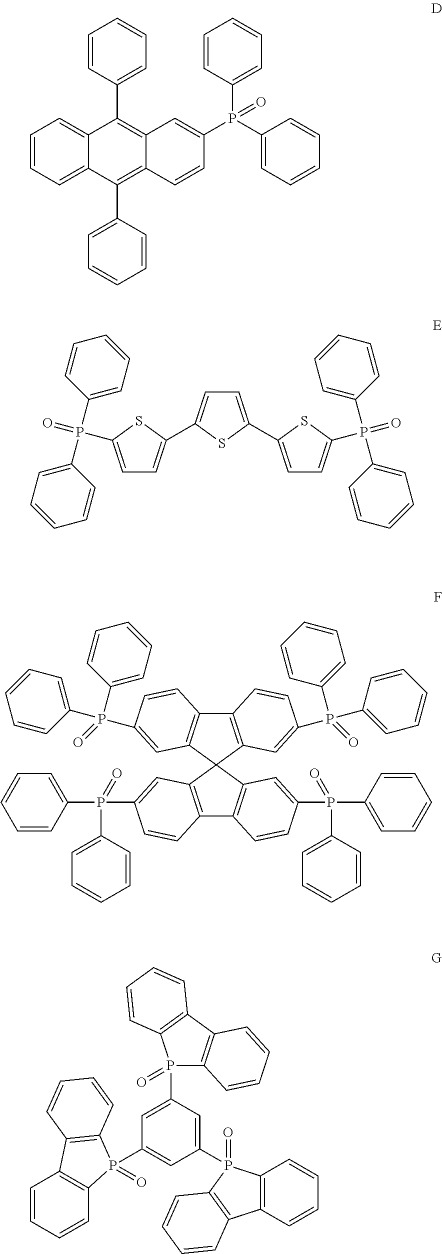

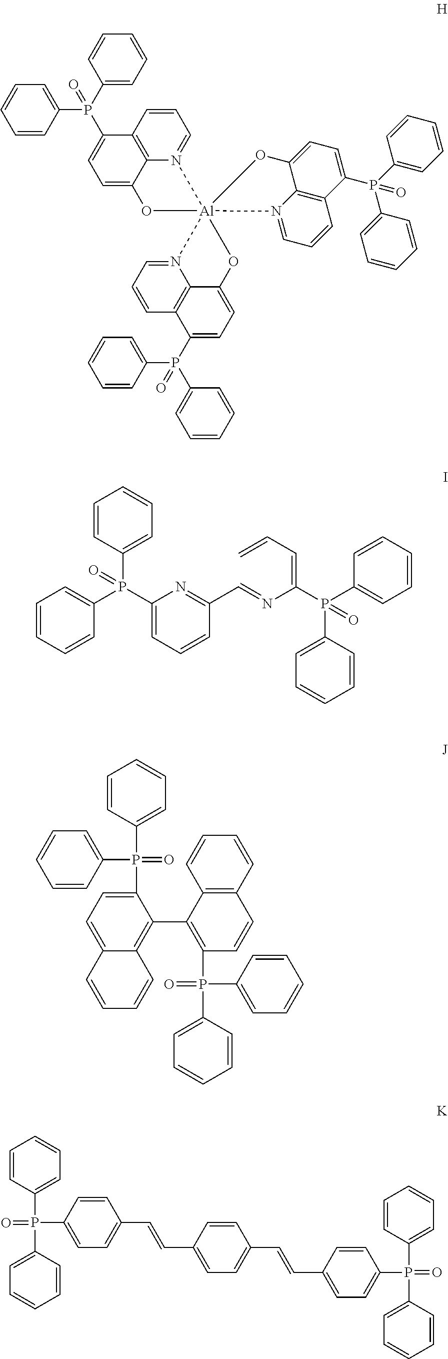

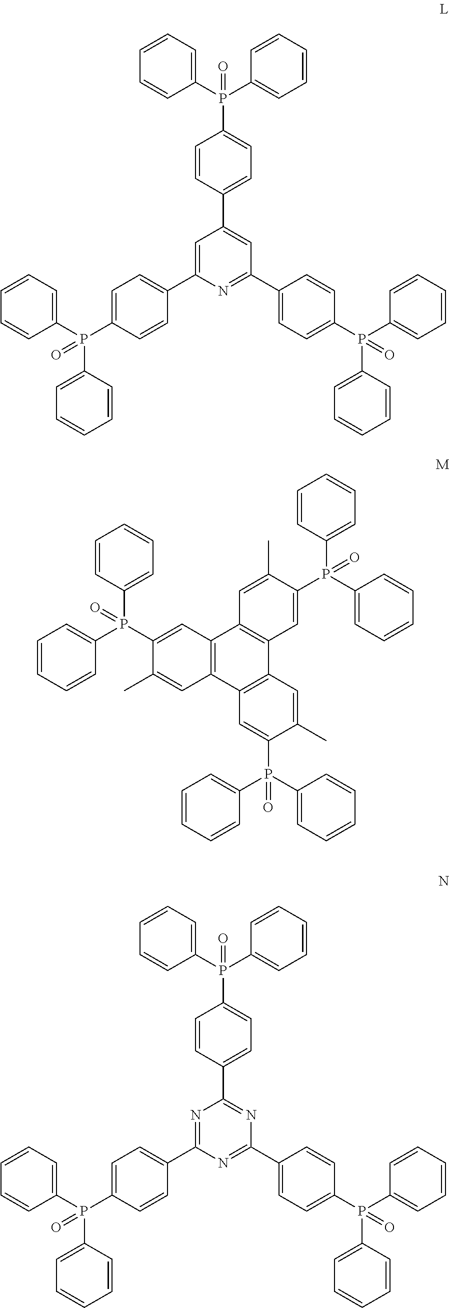

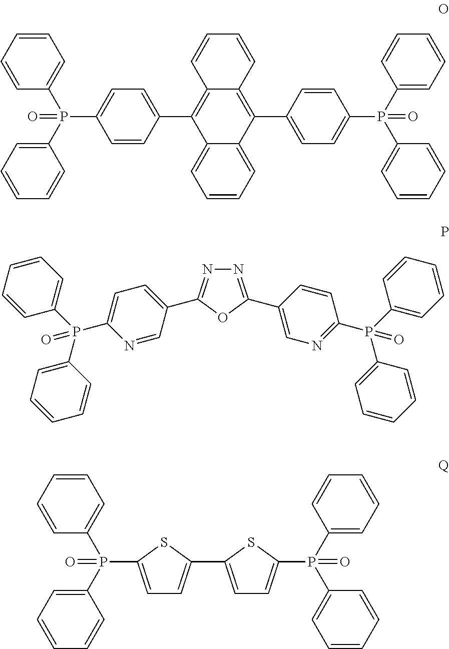

Commercially available phosphine oxide derivatives may be used as well as the phosphine oxide derivatives synthesized by any methods known in the art such as oxidation of tertiary phosphine, reaction of phosphinyl chloride or phosphoryl dichloride with Grignard reagent, coupling reaction of aryl halides and diaryl phosphine oxide, hydrolysis of dihalophosphorane and the like may also be used.

The phosphine oxide derivatives may be used alone or in combination of two or more of these derivatives mixed in any ratios. The electron injection, electron carrier and luminescence properties may be optimized by selecting the phosphine oxide derivatives or their combination depending on the materials of the cathode and the guest materials contained in the emissive layer 6 used for the production of the organic electroluminescent element 1.

### (II) Guest Material

One or more of any organic compounds and/or organic metal compounds soluble in alcohol solvent which can be excited electrically by recombination of injected electrons and holes to emit light may be selected as the organic compounds and/or organic metal compounds constituting the guest material. The organic compounds and/or organic metal compounds preferably have phosphine oxide moiety not coordinating to transition metal element or ion and more preferably are represented by Formula (3) shown below.

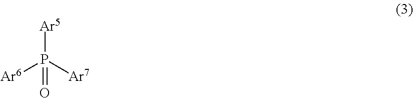

Ar⁵, Ar⁶ and Ar⁷ in Formula (3) are aryl or heteroaryl groups that may have one or more substituents independently of each other, and at least one of Ar⁵, Ar⁶ and Ar⁷ are luminescence aromatic moieties that can be excited electrically by recombination of injected electrons and holes to emit light.

The examples of the luminescent aromatic moiety include aryl or heteroaryl moieties such as 1,3,5-tris[(3-phenyl-6-trifluoromethyl)quinoxaline-2-yl]benzene (TPQ1), 1,3,5-tris[{3-(4-t-butylphenyl)-6-trifluoromethyl}quinoxaline-2-yl]benzene (TPQ2), and organic metallic compounds having aromatic ligand such as tris(8-hydroxyquinolilate) aluminum (Alq3), fac-tris(2-phenylpyridine)iridium(Ir(ppy)₃). Any one or any combination of two or more of these may be used.

An example of preferred guest material is the iridium complex represented by Formula (3)′ shown below, which is the organic electroluminescent material according to the second embodiment of the present invention.

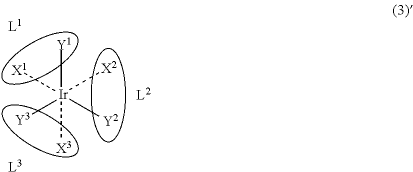

L¹, L² and L³ in Formula (3)′ are bidendate ligands, one or more of which comprise the luminescence aromatic moieties, X¹ and Y¹, X² and Y², and X³ and Y³ are coordinating atoms of L¹, L² and L³, respectively selected from the group consisting of carbon, oxygen and nitrogen atoms and at least one of L¹, L² and L³ have one or more phosphine oxide groups represented by Formula (2) shown below.

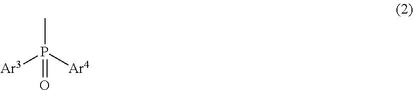

Ar³ and Ar⁴ in Formula (2) are aryl groups that may have one or more substituents independently of each other, where Ar³ and Ar⁴ may bind to form a heterocycle containing phosphorous atom.

More preferred guest materials are the iridium complexes represented by Formula (4) to (15) shown below and especially preferred guest material is the iridium complex represented by Formula (4)′.

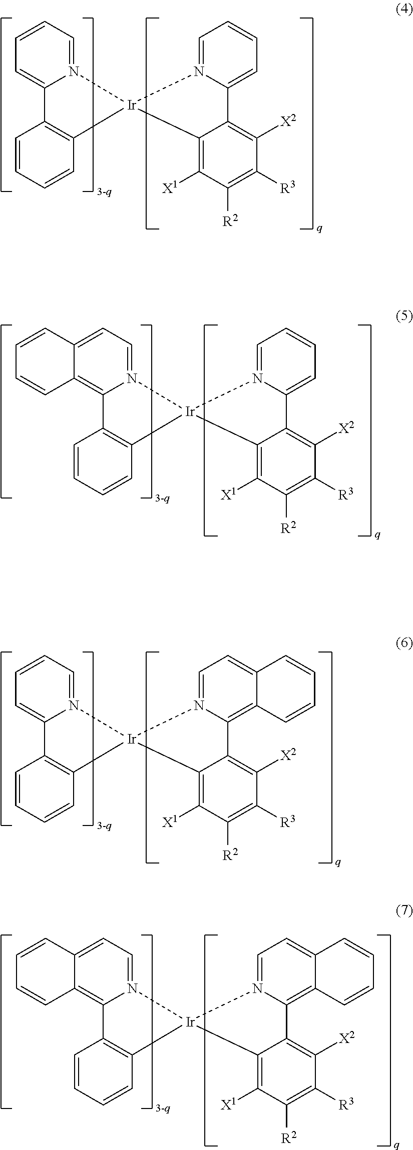

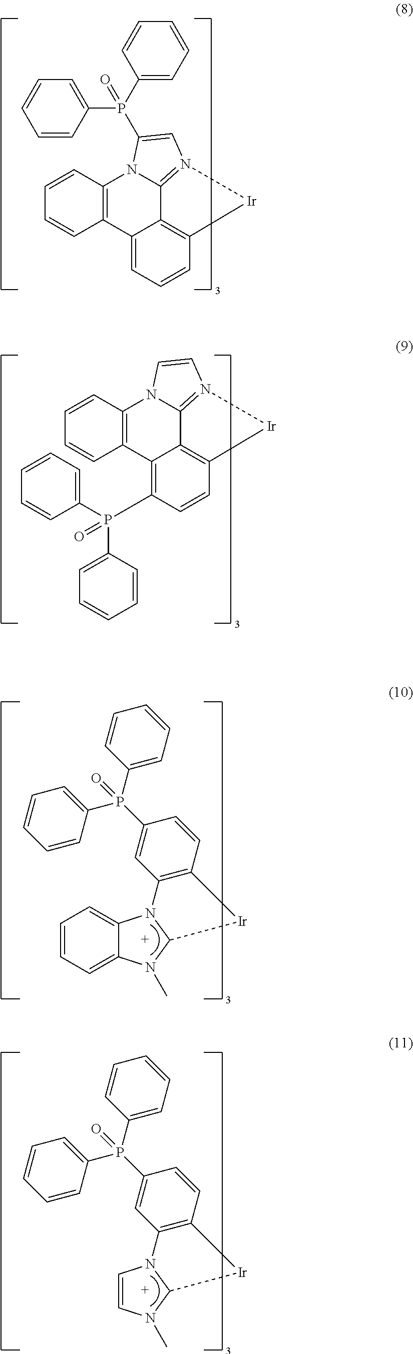

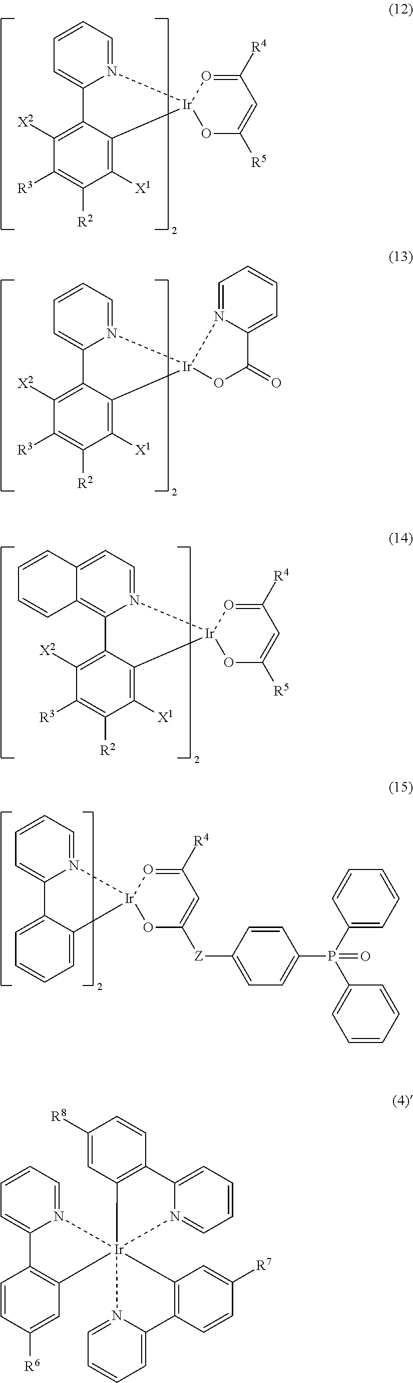

The one of R² and R³ in Formula (4) to (15) is hydrogen atom or phosphine oxide group represented by Formula (2) shown above, the other of R² and R³, X¹ and X² are selected from the group consisting of hydrogen and fluorine atoms independently of each other, q is an integer of 1, 2 or 3, R⁴ and R⁵ are groups selected from the group consisting of linear or branched alkyl groups having 1 to 12 carbon atoms, linear or branched fluoroalkyl groups having 1 to 12 carbon atoms, aryl groups and heteroaryl groups independently, and Z is direct bond or alkylene group having 1 to 12 carbon atoms. R⁶, R⁷ and R⁸ in Formula (4)′ are hydrogen atom or phosphine oxide group represented by Formula (2) shown above and at least one of R⁶, R⁷ and R⁸ are phosphine oxide group represented by Formula (2) shown above.

The emissive layer 6 may further comprise one or more salts or metal compounds of any metal element or ion with the electronegativity (χ) of 1.6 or less. Upon coordinating the metal element or ion of the metal salts and/or compounds to electron withdrawing phosphine oxide group, the electron transfer property and the electron injection property of the phosphine oxide derivative constituting the host material is further improved as well as its durability is significantly improved. Minimum value of the electronegativity is χ=0.79 for Cs.

Examples of the metal with the electronegativity (χ) of 1.6 or less are alkali metals (Li, Na, K, Rb and Cs), alkali earth metals (Be, Mg, Ca, Sr and Ba) and lanthanum (La). When the electronegativity is more than 1.6, the electron transfer property degrades because of decreasing of electron injection efficiency from the cathode. In transition metals other than lanthanum, the electron transfer property degrades because of quenching of excitation energy due to d-d transition and the like even when the electronegativity is 1.6 or less. Hence, salts of representative metal are preferred and the salts of alkali metals or alkali earth metals with small electronegativity are particularly preferred.

The compounds containing these metals are preferably metal alkoxide, β-diketonato complexes in which one or more β-diketone coordinate to the metal and the latter may be formed (complexation) in situ by reacting the salt soluble in alcohol solvent and free β-diketone in solution. In this case, the salt used is not particularly limited and any salts including halides such as chloride, nitrates, sulfonates, carbonates, acetates, sulfonates and the like may be used as long as they are soluble in alcohol solvent.

The β-diketones used for preparing the composition for forming the organic electron carrier material in free form or the ligand coordinating to central atom of the metal-β-diketonato complex are represented by Formula (19) shown below.

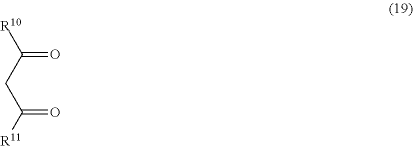

R¹⁰ and R¹¹ in Formula (19) are the functional group selected from the group consisting of linear or branched alkyl groups having 1 to 12 carbon atoms, linear or branched fluoroalkyl groups, aryl groups and heteroaryl groups independently of each other.

Examples of β-diketones preferably used as an additive of the emissive layer 6 include that are represented by the formulae shown below, which are acetylacetone (acac), 2,2,6,6-tetramethylheptane-3,5-dione (TMHD), 1,14-trifluoroacetylacetone (TFA) and 1,1,1,5,5,5-hexafluoroacetylacetone (HFA) from left to right.

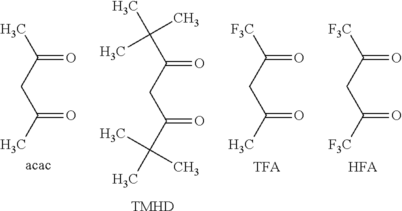

The formation of the emissive layer 6 by means of wet process may be carried out by applying the material for forming emissive layer prepared by dissolving the host material, guest material and metal salt or metal compound in alcohol solvent on the surface of the hole transport layer 5 followed by drying (removing solvent or dispersing medium).

The alcohol solvents used for the material for forming emissive layer include any alcohol solvents that hardly dissolve or swell the hole injection layer 4 or the hole transport layer 5 and have high solvilities toward the host material, guest material and metal salt or metal compound and are monoalcohols preferably having 1 to 7 carbon atom, more preferably having 1 to 4 carbon atoms. Examples of such alcohol solvents include methanol, ethanol, 1-propanol, 2-propanol, 1-butanol, 2-butanol, t-butyl alcohol, 1-pentanol, 1-hexanol and cyclohexanol. These solvents may be used alone or in combination of two or more of these derivatives mixed in any ratios.

Although preferable concentration range of the host material, guest material and metal salt or metal compound in the material for forming emissive layer may not be determined unambiguously since they depend on the solvilities and volatailabolity of the solvent, they are, for example, 0.1 to 5 weight percents, preferably 0.2 to 2 weight percents in total. When the concentrations of the host material, guest material and metal salt or metal compound are too low, it requires longer time to form the emissive layer 6 having sufficient thickness, which results in low productability. On the other hand, when the concentrations of the host material, guest material and metal salt or metal compound are too high, it may lead to precipitation of these materials or too viscous solution (the material for forming emissive layer), which results in poor workability.

Preparation of the composition for forming the organic electron transport material may be carried out by mixing the solution of each material prepared separatedly. In this case, the solvent used for each solution may be similar or different with each other as long as homogeneous resultant solution may be obtained. This enables to prepare the solution even if the solubilities of the phosphine oxide derivatives and the metal compounds are largely different and it is difficult to mix these materials in desired ratio. Moreover, mixing of the host material, guest material and metal salt or metal compound makes in desired ratios is possible by means of any methods for preparing the liquid materials mentioned above. The content of the guest material is preferably 1 to 25 weight percents of that of the host material. The content of the metal salt or the metal compound is preferably 1 to 50 weight percents of that of the host material.

The emissive layer 6 may further comprise other luminescent material(s). In this case, the luminescent material added is necessary to be soluble in alcohol solvent.

Average thickness of the emissive layer 6 is not particularly limited, preferably about 10 to 150 nm and more preferably about 40 to 100 nm.

The sealant 8 is situated so that it covers the organic electroluminescent element 1 (the anode 3, the hole injection layer 4, the hole transport layer 5, the emissive layer 6 and the cathode 7) and has the function of sealing them airtight and shut out oxygen and moisture. The sealant 8 has the effects of enhancing the reliability of the organic electroluminescent layer 1 and preventing from degrading and deteriorating (enhancing the durability).

Examples of the constituent material of the sealant 8 include Al, Au, Cr, Nb, Ta, Ti or alloy containing these metals, silicon oxide and plastics. When a conducting material is used as the constituent material of the sealant 8, it is preferred to form an insulating layer between the organic electroluminescent element 1 and the sealant 8 as needed to prevent a short circuit. The plate-like sealant 8 may be faced to the substrate 2 and they may be bound with each other by, for example, a thermosetting resin and the like.

Between the emissive layer 6 and the cathode 7, an electron transport layer not shown in FIG. 1 may be formed. The electron transport layer has the function of carrying electrons injected from the cathode 7 to the emissive layer 6. Examples of the constituent material of the electron transport layer include, for example, triazole derivatives, oxazole derivatives, oxadiazole derivatives, imidazole derivatives, fluorenone derivatives, anthraquinodimethane derivatives, anthrone derivatives, diphenylquinone derivatives, thiopyranedioxide derivatives, carbodiimide derivatives, fluorenylidenemethane derivatives, distyrylpyradine derivatives, carboxylic anhydride derivatives of naphthalene and perilene and the like, phthalocyanine derivatives, metal complex of 8-quinolinol and metallophthalocyanine, metal complexes having benzooxazole or benzothiazole ligands and organosilane derivatives.

The electron transport layer may contain electron-donating dopant. The electron-donating dopant to be included in the electron transport layer may be any electron-donating materials that can reduce organic compounds and alkali metals such as Li, alkali earthmetals such as Mg, transition metals containing rare earth metals and reductant organic compounds. Examples of metal include Li, Na, K, Be, Mg, Ca, Sr, Ba, Y, Cs, La, Sm, Gd and Yb. Examples of reducing organic compound include nitrogen-containing compounds, sulfur-containing compounds and phosphorus-containing compounds (including the phosphine oxide derivatives used as the host materials in the emissive layer 6). The materials described in Japanese published unexamined application No. 1994-212153, Japanese published unexamined application No. 2000-196140, Japanese published unexamined application No. 2003-68468, Japanese published unexamined application No. 2003-229278 and Japanese published unexamined application No. 2004-342614 and the like may also be used.

Average thickness of the electron transport layer is not particularly limited, preferably about 1 to 100 nm and more preferably about 10 to 50 nm. Moreover, an electron injection layer consisting of LiF and the like may be formed between the cathode 7 and the emissive layer 6 or the electron transport layer as needed.

The organic electroluminescent element 1 may be produced, for example, as followings.

At first, a substrate 2 is provided, on which an anode 3 is formed.

The anode 3 may be formed by, for example, chemical vapor deposition (CVD) such as plasma CVD, thermal CVD, laser CVD; dry plating such as vacuum deposition, sputtering and ion plating; wet plating such as electrolytic plating, immersion plating and electroless plating; thermal spray; sol-gel method; MOD process; bonding of metal foil and the like.

Then, the hole injection layer 4 and the hole transport layer 5 are successively formed on the anode 3.

The formation of the hole injection layer 4 and the hole transport layer 5 may be carried out, for example, by applying the material for forming hole injection layer prepared by dissolving or dispersing the hole injection material in solvent or dispersing media on the surface of the anode 3 followed by drying (removing solvent or dispersing medium), then applying the material for forming hole transport layer prepared by dissolving or dispersing the hole transport material in solvent or dispersing media on the surface of the hole injection layer 4 followed by drying (removing solvent or dispersing medium). Examples of the method for applying the material for forming the hole injection layer or the material for forming the hole transport layer include coating methods such as a spin coating, a casting method, a microgravure coating method, a gravure coating method, a bar coating method, a roll coating method, a wire bar coating method, a dip coating method, a spray coating method, a screen printing method, a flexoprinting method, an offset printing method, an inkjet printing method. By the use of such coating methods, the hole injection layer 4 and the hole transport layer 5 may be formed relatively easily.

The solvents and dispersion media used for forming the materials for the hole injection layer and the hole transport layer include, for example, inorganic solvents such as nitric acid, sulfuric acid, ammonia, hydrogen peroxide, water, carbon disulfide, carbon tetrachloride, and ethylene carbonate; ketone solvents such as methylethyl ketone (MEK), acetone, diethyl ketone, methylisobutyl ketone (MIBK), methylisopropyl ketone (MIPK), cyclohexanone; alcohol solvents such as methanol, ethanol, isopropyl alcohol, ethyleneglycol, diethyleneglycol (DEG), and glycerol (when the hole injection materials and the hole transport materials are insoluble in these solvents, alcohol solvents may be only used as dispersion media); ether solvents such as diethyl ether, diisopropyl ether, 1,2-dimethoxyethane (DME), 1,4-dioxane, tetrahydrofuran (THF), tetrahydropyran (THP), anisole, diethyleneglycol dimethyl ether (diglyme) and diethyleneglycol ethyl ether (carbitol); cellosolve solvents such as methyl cellosolve, ethyl cellosolve and phenyl cellosolve; aliphatic hydrocarbon solvents such as hexane, pentane, heptane and cyclohexane; aromatic hydrocarbon solvents such as toluene, xylene and benzene; heteroaromatic solvents such as pyridine, pyradine, furan, pyrrole, thiophene and N-methylpyrrolidone; amide solvents such as N,N-dimethylformamide (DMF) and N,N-dimethylacetoamide (DMA); halogenated hydrocarbon solvents such as chlorobenzene, dichloromethane, chloroform and 1,2-dichlroethane; ester solvents such as ethyl acetate, methyl acetate and ethyl formate; sulfer compound solvents such as dimethylsulfoxide (DMSO) and sulfolane; nitrile solvents such as acetonitrile, propionitrile and acrylonitrile; organic acid solvents such as formic acid, acetic acid, trichloroacetic acid, trifluoroacetic acid; or mixtures thereof.

Drying may be carried out, for example, by standing at atmospheric pressure or under reduced pressure, heating, blowing by inert gas and the like.

Prior to these processes, oxygen plasma processing on the top surface of the anode 3 may be carried out. This enables to provide affinity to liquid on the top surface of the anode 3, remove (wash) the organic compounds attached on the top surface of the anode 3 and adjust the work function of the anode 3 around the top surface and the like.

The preferred conditions of the oxygen plasma processing are, for example, plasma power of about 100 to 800 W, flow rate of oxygen gas of about 50 to 100 mL/min, movement speed of the work (the anode 3) of about 0.5 to 10 mm/sec, and the temperature of the substrate 2 of 70 to 90° C.

Then the emissive layer 6 is formed on the surface opposite to the anode 3 of the hole transport layer 5.

The emissive layer 6 may be formed by applying the material for forming emissive layer prepared by dissolving the aforementioned host material and the guest material in the solvent or dispersed them in the dispersion media on the surface of the hole transport layer 5 followed by drying (removing solvent or dispersing medium). The method for applying the material for forming emissive layer and for drying are similar to those described in the formation of hole injection layer 4 and the hole transport layer 5.

Then, the electron transport layer is formed by applying the organic electron transport material on the surface of the emissive layer 6 followed by drying, as needed. As the method for applying the organic electron transport material and for drying are similar to those described in the formation of hole injection layer 4 and the hole transport layer 5, description is omitted.

Then, the cathode 7 is formed on the surface of the electron transport layer (opposite to the emissive layer 6).

The cathode 7 may be formed, for example, by vacuum deposition, sputtering, bonding of metal foil, application of metal fine particle ink followed by sintering.

Finally, the organic electroluminescent element 1 is covered by the sealant 8 and bound to the substrate 2. Thus, the organic electroluminescent element 1 is obtained.

According to the production method as described above, formation of organic layers (the hole injection layer 4, the hole transport layer 5 and the emissive layer 6) as well as the formation of the cathode 7 in case that the metal fine particle ink is used, the time and cost required for the production of the organic electroluminescent element 1 may be reduced since the formation of these layers does not require large-scale facility such as the vacuum system. Applycation of inkjet printing method makes the production of large element and polychrome printing easier.

Although the hole injection layer 4 and the hole carrier lay 5 are formed by wet process in this embodiment, these layers may be formed by dry process such as vacuum deposition method depending on the kind of the hole injection material and the hole transport material.

For example, such organic electroluminescent element 1 may be used for a light source. A plurality of the organic electroluminescent elements may be arranged in a matrix array to form a display unit.

Drive system of the display unit is not particularly limited, which may be either active matrix system or passive matrix system.

Electric power supply for the organic electroluminescent element 1 is mainly direct current, however, pulse current or alternative current may also be used. Values of the current and voltage are not particularly limited, however, taking the power consumption and the lifetime of the element into consideration, they should be adjusted so that the maximum luminescence may be achieved by minimum power consumption.

The “matrix” forming the display unit refers to a grid-like array of pixels and displays characters and images by an assembly of the pixels. Shape and size of the pixels are determined depending on the applications. For example, displays for characters and images of personal computer, monitor and television, square-shaped pixels, 300 μm or less on a side are employed whereas large-scale displays such as display panel employ the pixels having the size of a few mm. While a monochrome display only requires pixels of single color, color display requires red, green and blue pixels are to be arranged to display informations. Typical pixel arrays include delta type array and stripe type array. Both of the passive matrix system and the active matrix system may be employed as the driving system of pixel array. The former has the advantage to its simple structure, however, in some cases, the active matrix system is more suitable taking into its operating characteristics into consideration. Therefore, both systems are to be chosen according to the application of the display unit.

The organic electroluminescent element 1 may be a segment type display unit. In the “segment type” unit, the emissive layer 6 is formed in a pattern of certain shape so that predetermined informations are displayed by the emission of certain segment(s) of the element 1. Examples of such unit include display of digital clocks and thermometers, status monitor of audio devices and electromagnetic cookers, instrument panel of automobiles. Both of the matrix display unit and the segment type display unit may be on the same display panel.

The organic electroluminescent element 1 may be used to enhance the visibility of non-self luminescent display unit, which may be a backlight unit of liquid crystal display units, clocks, audio devices, instrument panel of automobiles, display panels and sign boards. In particular, liquid crystal display units, especially the backlight of personal computers of which thinnerization is a problem to be solved, it can be made thinner and lighter comparing with those known in the art consisting of fluorescent lamp or light guiding panel.

### (2) Organic Electroluminescent Material

The organic electroluminescent material according to the second embodiment of the present invention is an iridium complex having the structure represented by Formula (3)′, preferably Formula (4) to (15) shown below.

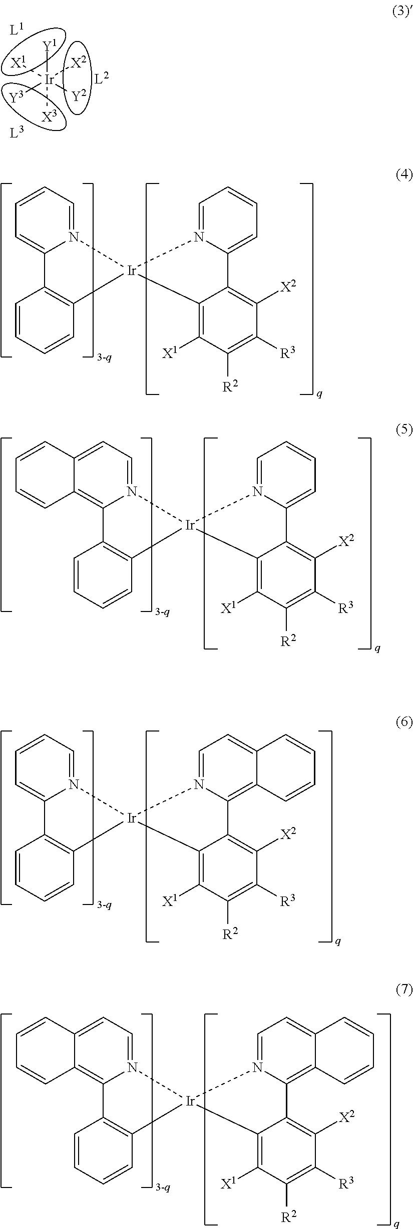

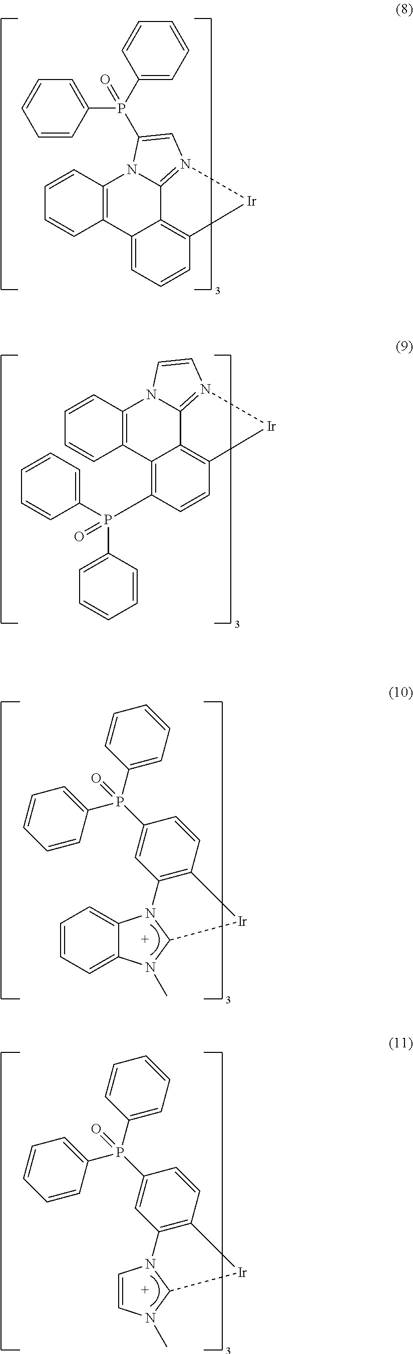

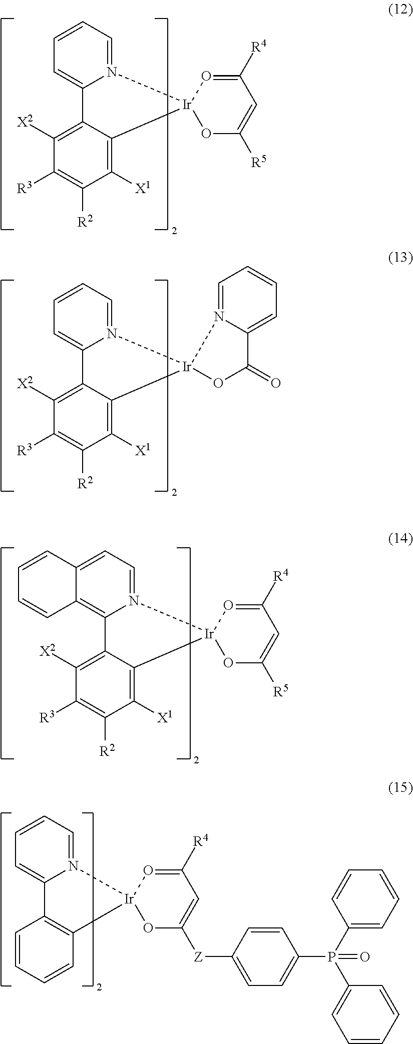

L¹, L² and L³ in Formula (3)′ are bidendate ligands, X¹ and Y¹, X² and Y², and X³ and Y³ are coordinating atoms of L¹, L² and L³, respectively selected from the group consisting of carbon, oxygen and nitrogen atoms and at least one of L¹, L² and L³ have one or more phosphine oxide groups represented by Formula (2) shown below.

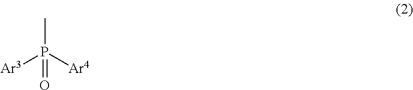

Ar³ and Ar⁴ in Formula (2) are aryl groups that may have one or more substituents independently of each other, where Ar³ and Ar⁴ may bind to form a heterocycle containing phosphorous atom.

The one of R² and R³ in Formula (4) to (15) is hydrogen atom or phosphine oxide group represented by Formula (2) shown above, the other of R² and R³, X¹ and X² are selected from the group consisting of hydrogen and fluorine atoms independently of each other, q is an integer of 1, 2 or 3, R⁴ and R⁵ are groups selected from the group consisting of linear or branched alkyl groups having 1 to 12 carbon atoms, linear or branched fluoroalkyl groups having 1 to 12 carbon atoms, aryl groups and heteroaryl groups, and Z is direct bond or alkylene group having 1 to 12 carbon atoms.

Among these compounds, the particularly preferred compound is the iridium complex having the structure represented by Formula (4)′ shown below (in Formula (4), R² is diarylphosphine oxide group on para-position of 2-pyridyl group and R³, X¹ and X² are hydrogen atoms).

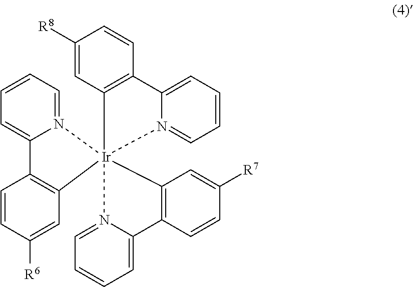

R⁶, R⁷ and R⁸ in Formula (4)′ are hydrogen atom or phosphine oxide group represented by Formula (2) shown above and at least one of R⁶, R⁷ and R⁸ are phosphine oxide group represented by Formula (2) shown above.

The ligands of the iridium complexes represented by Formula (4) to (15) having 2-phenylpyridine skeleton or 1-phenylisoquinoline skeleton may be synthesized according to, for example, the Scheme 1 or 2 shown below. According to Scheme 1 and 2 describing the syntheses of the ligands having 2-phenylpyridine skeleton, the ligands having 1-phenylisoquinoline skeleton may also be synthesized by using 1-chloroisoquinoline instead of 2-bromopyridine. In addition, phosphine derivative obtained according to Scheme 1 using diphenylchlorophosphine instead of diphenylphosphinyl chloride may be converted to corresponding phosphine oxide derivative by oxidation using, for example, hydrogen peroxide.

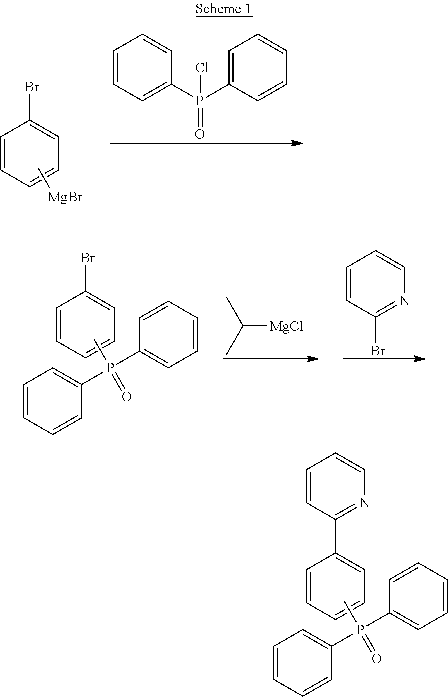

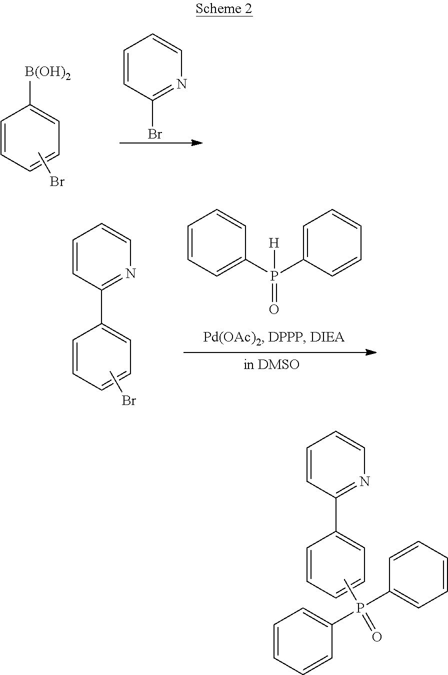

The ligands thus obtained are reacted with IrCl₃.3H₂O to afford chloro-bridged binuclear complexes, which are further reacted with ligand to give the target iridium complex (see Scheme 3).

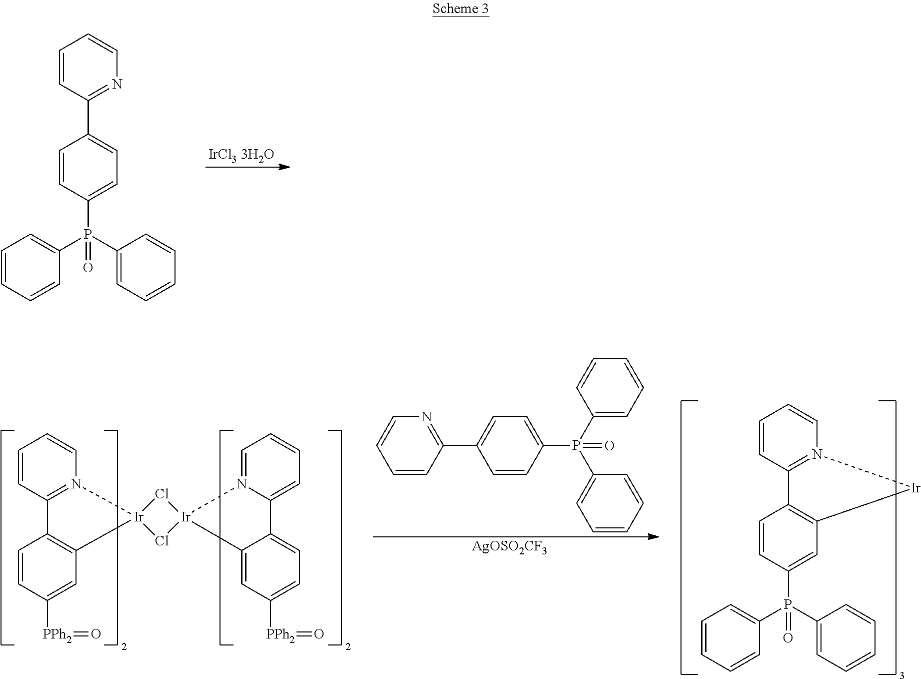

Alternatively, the chloro-bridged binuclear complexes may be reacted with acetonitrile in the presence of silver salt followed by reacting with the ligand (see Scheme 4).

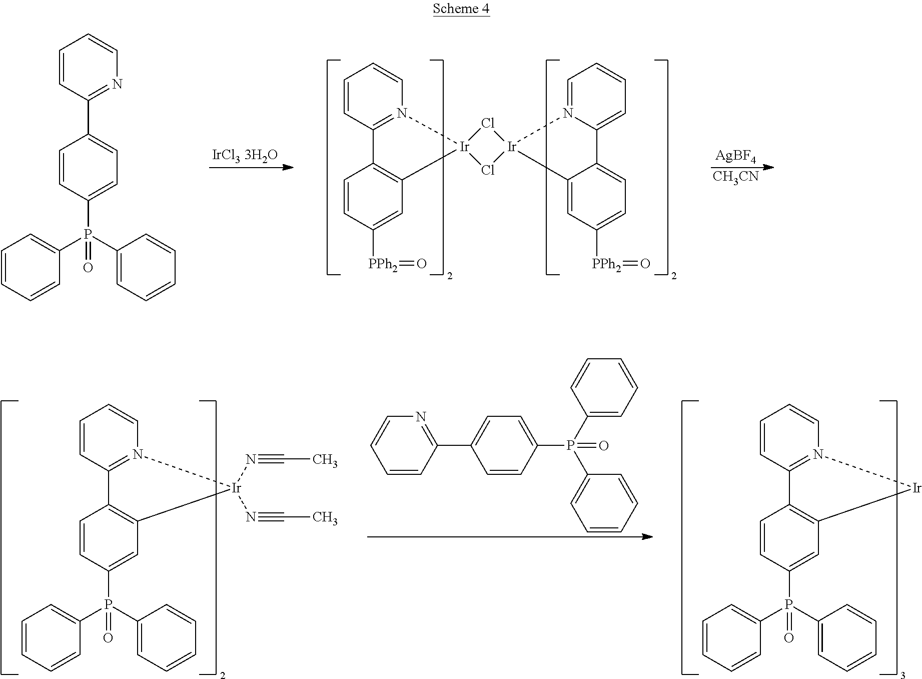

The iridium complexes thus obtained have two isomers (meridional (mer-) form and facial (fac-) form) arise from the configuration of the ligands as shown below. The ratio of these isomers varies depending on the reaction condition and the like. Both isomers exhibit phosphorescence emission, however, fac-form generally have longer luminescent lifetime and higher quantum yield. Therefore, mer-form may be converted to fac-form by ultraviolet irradiation and the like in case that mixture of these two isomers are obtained.

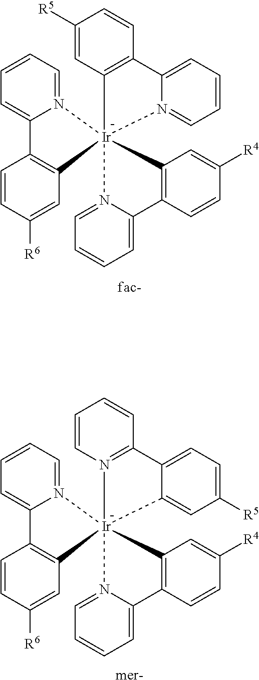

The ligand of the iridium complex represented by Formula (8) 3-(diphenylphosphoryl)imidazo[1,2-f]phenanthridine may be synthesized according to the method shown in Scheme 5. Starting form this ligand, the iridium complex may be synthesized according to the method similar to that of Scheme 3. However, β-diketones such as acetylacetone may be used instead of acetonitrile.

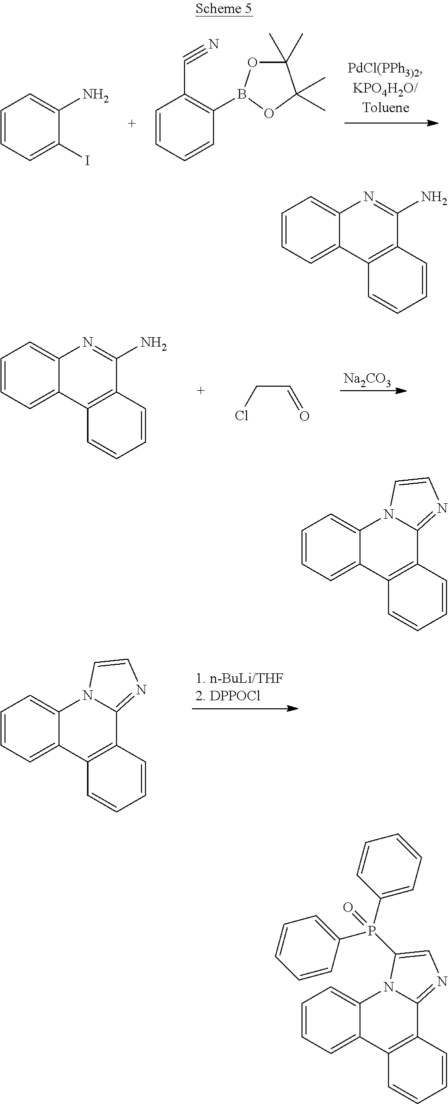

The ligand of the iridium complex represented by Formula (10), 1-(3-(diphenylphosphoryl)phenyl)-3-methyl-imidazorium iodide may be synthesized according to the method shown in Scheme 6. The ligands thus obtained are reacted with IrCl₃ to afford the target iridium complex (see Scheme 7).

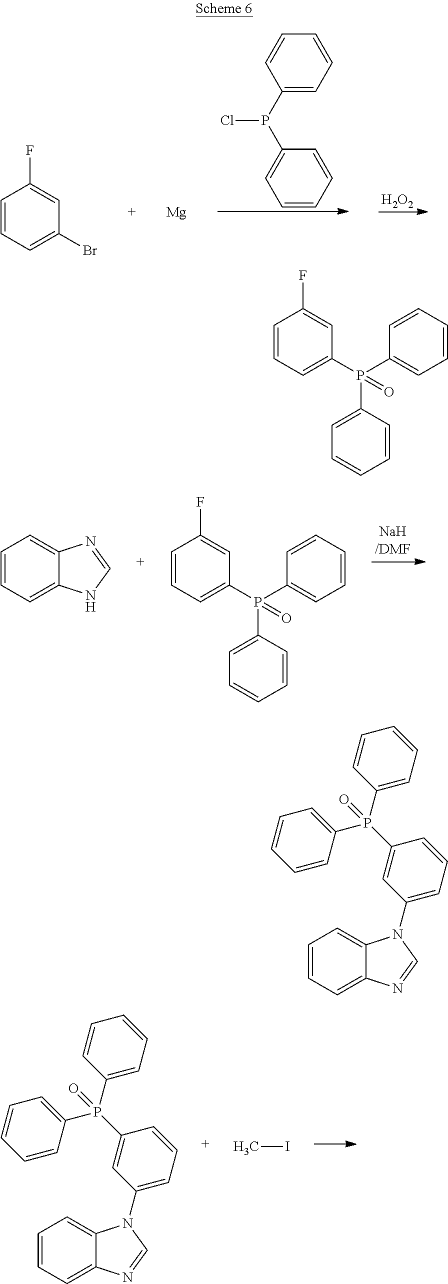

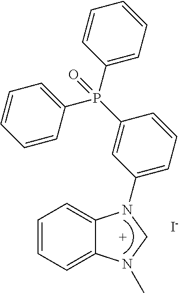

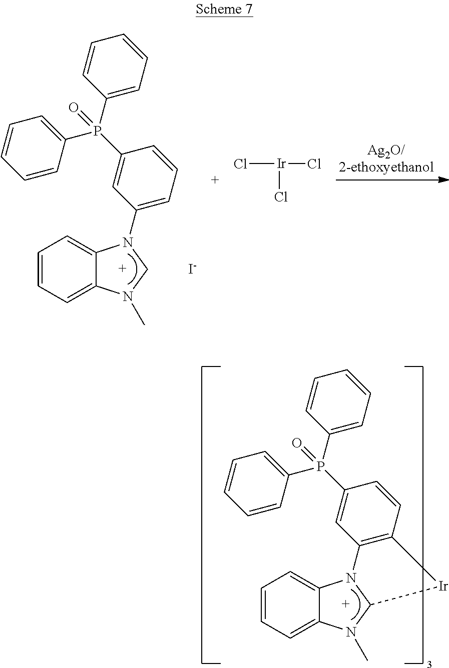

The iridium complexes represented by Formula (12), (14) and (15) may be synthesized by reacting the chloro-bridged binuclear complex synthesized according to the method shown in anterior part of Scheme 3 with the β-diketone represented by Formula (19) shown above (see Scheme 8). The iridium complex represented by Formula (13) may be synthesized similarly except that picoline acid is used instead of the β-diketone.

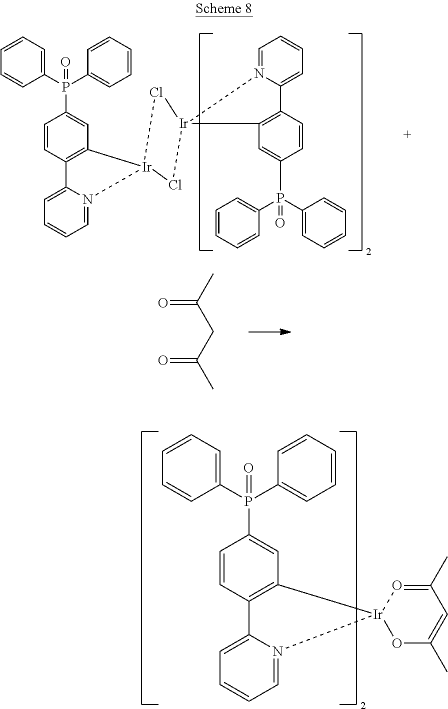

### EXAMPLES

Hereinafter, the examples for confirming the effect of the present invention will be described.

### (1) Synthesis of Host Materials

Among the host materials used (phosphine oxide derivatives: represented by Formula A to Q shown above), what are described in PCT Gazett WO 2005/104628 were synthesized according to the described method in the Gazett.

### (2) Synthesis of Guest Material

### [I] Synthesis of [bis(2-phenylpyridinato-N,C^{2′})-mono(2-(4-diphenylphosphoryl) pyridinato-N,C^{2′})]iridium (III) (Ir(ppy)₂(pdppy))

### (I-1) Synthesis of 4-bromophenyldiphenylphosphine oxide (pBrdppo)

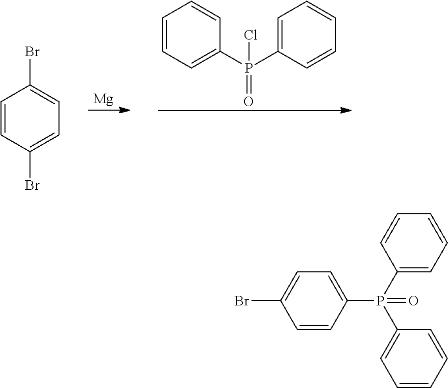

To 2.16 g (88.9 mmol) of magnesium, 5 mL of THF was added, then a THF solution of 22 g of 1,4-dibromobenzene (93.2 mmol) was added dropwise at 0° C. The mixture was stirred until all magnesium was consumed, then 40 mL of THF was added and the mixture was stirred for 1 hour. The mixture was cooled to 0° C. and 15.7 mL of diphenylphosphoryl chloride (84.5 mmol) was added dropwise. The mixture was stirred overnight at room temperature. After the reaction completed, 1N HCl was added to hydrolyze. The mixture was extracted with dichloromethane and the organic layer was dried over magnesium sulfate. The organic layer was concentrated and purified with silica gel column chromatography (eluent: dichloromethane/ethanol). The fraction was concentrated and recrystallized from cyclohexane. The peak at m/z=357([M]⁺) was observed in FAB-MS. Yield: 13.4 g (44.2%).

### (I-2) Synthesis of 2-[(4-diphenylphosphoryl)phenyl]pyridine (pdppy)

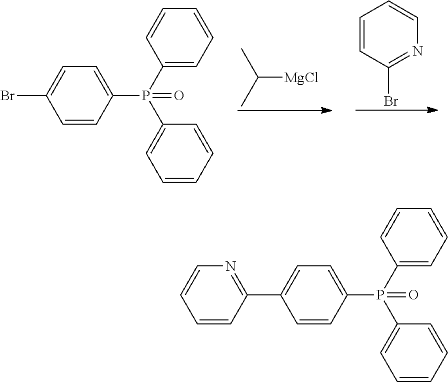

To the solution of 4.28 g of pBrdppo (synthesized according to I-1) (12 mmol) in 12 mL of THF, 7 mL of a solution of isopropylmagnesium chloride (iPrMgCl) (2 M diethyl ether solution, 14 mmol) was added dropwise at room temperature and the mixture was stirred for 2 hours. 0.22 g of [1,3-bis(diphenylphosphino)propane]dichloronickel(II) (Ni(dppp)Cl₂) (0.4 mmol) and 1.55 mL of 2-bromopyridine (16 mmol) was added and the mixture was refluxed for 48 hours. After the reaction completed, the reaction mixture was quenched with saturated aqueous solution of ammonium chloride added. The mixture was extracted with dichloromethane twice. The organic layer was extracted with 6N HCl twice. The aqueous layer was neutralized and extracted with dichloromethane. The organic layer was dried over magnesium sulfate. The organic layer was concentrated and purified with silica gel column chromatography (eluent: dichloromethane/ethanol). The fraction was concentrated with rotary evaporator and recrystallized from cyclohexane. The peak at m/z=356([M+1]⁺) was observed in FAB-MS. Yield: 2.04 g (47.9%).

### (I-3) Synthesis of tetrakis(2-phenylpyridinato-N,C^{2′})(μ-dichloro)diiridium (III) ([Ir(ppy)₂Cl]₂)

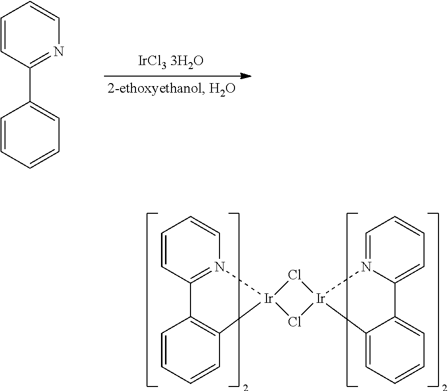

To 0.25 g of 2-phenylpyridine (1.6 mmol) and 0.23 g of iridium chloride (0.66 mmol), 10 mL of 2-ethoxyethanol of 3 mL of water were added and the mixture was refluxed overnight. After the reaction completed, the mixture was cooled to room temperature and water was added to precipitate the product. The precipitate was filtrated. The peak at m/z=536([M/2]⁺) was observed in FAB-MS. Yield: 0.32 g (90.1%).

### (I-4) Synthesis of [bis(2-phenylpyridinato-N,C^{2′})-mono(2-(4-diphenylphosphoryl phenyl)pyridinato-N,C^{2′})]iridium(III) (Ir(ppy)₂(pdppy))

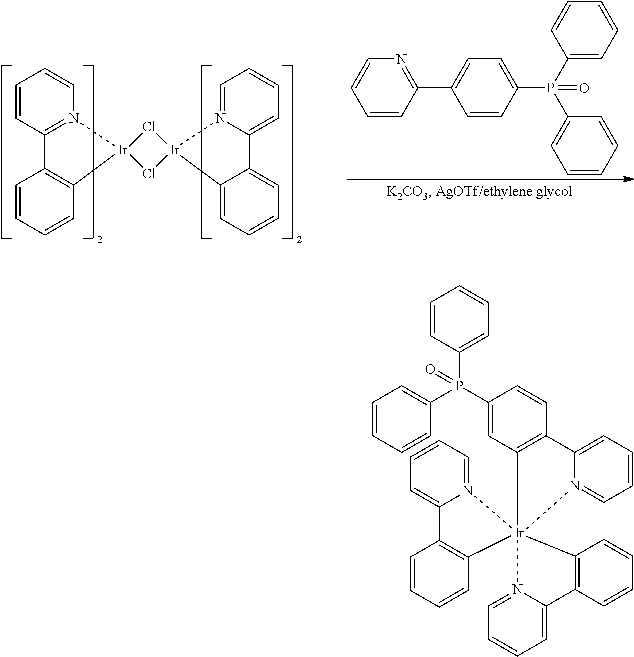

To 0.54 g of [Ir(ppy)₂Cl]₂ (synthesized according to 1-3) (0.5 mmol), 0.5 g of pdppy (synthesized according to 1-2) (1.4 mmol), 0.34 g of potassium carbonate (2.5 mmol) and 0.32 g of silver trifluoromethane sulfonate (1.23 mmol), 13 mL of ethyleneglycol was added and the mixture was refluxed overnight. After the reaction completed, dichloromethane was added and the mixture was filtrated with Celite to remove impurities. The filtrate was concentrated and purified with silica gel column chromatography (eluent: dichloromethane/ethanol). The peak at m/z=855([M]⁺) was observed in FAB-MS. Crude yield: 0.27 g (31.8%).

### [II] Synthesis of [mono(2-phenylpyridinato-N,C^{2′})-bis(2-(4-diphenylphosphoryl phenyl)pyridinato-N,C^{2′})]iridium(III) (Ir(ppy)(pdppy)₂)

### (II-1) Synthesis of tetrakis(2-(4-diphenylphosphorylphenyl)pyridinato-N,C^{2′}) (μ-dichloro)diiridium(III) ([Ir(pdppy)₂Cl]₂)

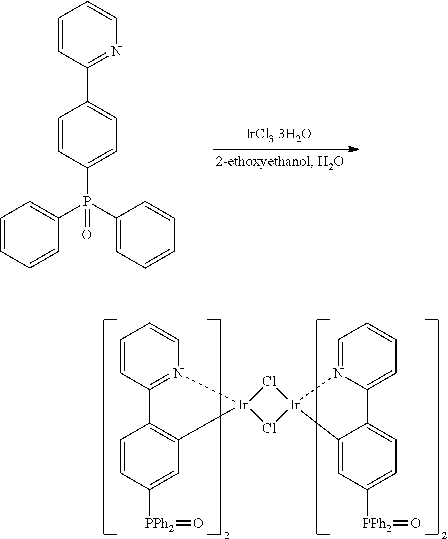

To 0.29 g of pdppy (synthesized according to 1-2) (0.82 mmol) and 0.12 g of iridium chloride (0.33 mmol), 5 mL of 2-ethoxyethanol and 1.5 mL of water were added and the mixture was refluxed overnight. After the reaction completed, the mixture was cooled to room temperature and water was added to precipitate the product. The precipitate was filtrated. The peaks at m/z=937([M/2]⁺, 901[(M-Cl)/2]⁺) were observed in FAB-MS. Yield: 0.28 g (90.6%).

### (II-2) Synthesis of [mono(2-phenylpyridinato-N,C^{2′})-bis(2-(4-diphenylphosphoryl phenyl)puridinato-N,C^{2′})]iridium(III) (Ir(ppy)(pdppy)₂)

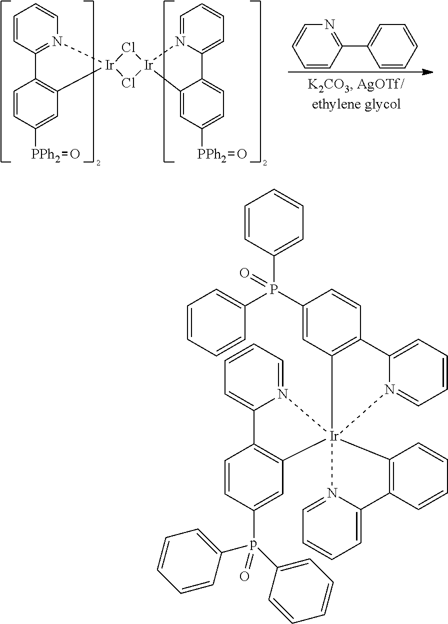

To 0.19 g of [Ir(pdppy)₂Cl]₂ (synthesized according to II-1) (0.1 mmol), 0.04 mL of 2-phenylpyridine (0.28 mmol), 0.076 g of potassium carbonate (0.51 mmol) and 0.063 g of silver trifluoromethane sulfonate (0.25 mmol), 2.6 mL of ethyleneglycol was added and the mixture was refluxed overnight. After the reaction completed, the mixture was cooled, then chloroform was added and the mixture was filtrated with Celite to remove impurities. The filtrate was concentrated and purified with silica gel column chromatography (eluent: dichloromethane/ethanol) to separate the product. The peaks at m/z=1054([M−1]⁺) and 1056 ([M+1]⁺) were observed in FAB-MS. Crude yield: 0.13 g (61.9%).

### [III] Synthesis of [tris(2-(4-diphenylphosphorylphenyl)pyridinato-N,C^{2′})]iridium (III) (Ir(pdppy)₃)

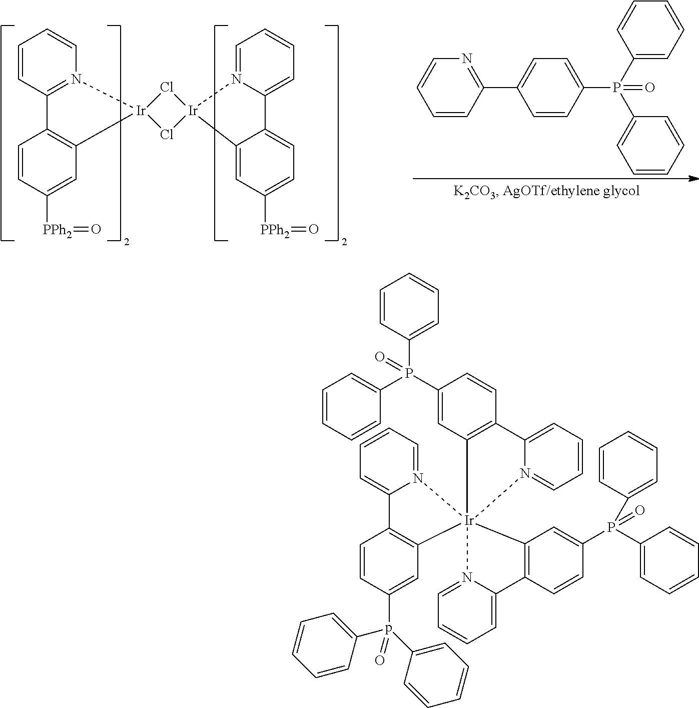

To 0.76 g of [Ir(pdppy)₂Cl]₂ (synthesized according to II-1) (0.406 mmol), 0.41 g of pdppy (synthesized according to I-2) (0.15 mmol) and 0.29 g of potassium carbonate (2.09 mmol), 11 mL of ethyleneglycol was added and the mixture was stirred for 32 hours at 200° C. After the reaction completed, dichlormethane was added and the mixture was filtrated with Celite. The filtrate was concentrated with rotary evaporator and purified with silica gel column chromatography (eluent: dichloromethane/ethanol). The peak at m/z=1257 ([M+2]⁺) was observed in FAB-MS. Crude yield: 0.3 g (30%).

### [IV] Synthesis of [bis(2-phenylpyridinato-N,C^{2′})-mono(2-(3-diphenylphosphoryl phenyl)pyridinato-N,C^{2′})]iridium(III) (Ir(ppy)₂(mdppy)

### (IV-1) Synthesis of mdppy (The Method Using Diphenylphosphinyl Chloride)

### (IV-1-1) Synthesis of 3-bromodiphenylphosphine oxide (mBrdppo)

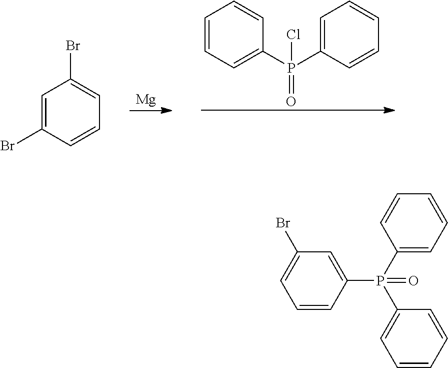

To 0.24 g (10 mmol) of magnesium, 0.6 mL of THF was added, then a THF solution of 2.45 g of 1,3-dibromobenzene (10.4 mmol) was added dropwise at 0° C. The mixture was stirred until all magnesium was consumed, then 4 mL of THF was added and the mixture was stirred for 1 hour. The mixture was cooled to 0° C. and 1.83 mL of diphenylphosphinyl chloride (9.5 mmol) was added dropwise. The mixture was stirred overnight at room temperature. After the reaction completed, 10% HCl was added to hydrolyze. The mixture was extracted with dichloromethane and the organic layer was dried over magnesium sulfate. The organic layer was concentrated and purified with silica gel column chromatography (eluent: dichloromethane/ethanol). The fraction was concentrated and recrystallized from cyclohexane. The peak at m/z=357([M]⁺) was observed in FAB-MS. Yield: 0.82 g (23.0%).

### (IV-1-2) Synthesis of 2-[(3-diphenylphosphoryl)phenyl]pyridine (mdppy)

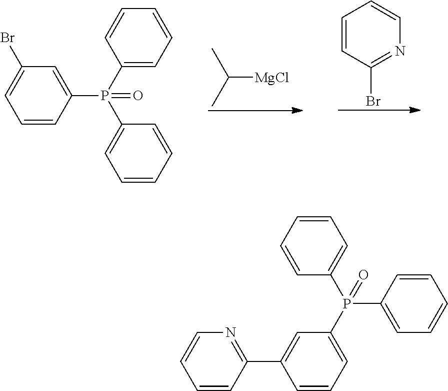

To the solution of 3.21 g of mBrdppo (synthesized according to IV-1-1) (9 mmol) in 9 mL of THF, 5.25 mL of a solution of isopropylmagnesium chloride (iPrMgCl) (2 M diethyl ether solution, 10.5 mmol) was added dropwise and the mixture was stirred for 2 hours at room temperature. To 0.16 g of [1,3-bis(diphenylphosphino)propane]dichloronickel(II) (Ni(dppp)Cl₂) (0.3 mmol) and 1.16 mL of 2-bromopyridine (12 mmol) was added and the mixture was refluxed for 48 hours. After the reaction completed, the reaction mixture was quenched with saturated aqueous solution of ammonium chloride added. The mixture was extracted with dichloromethane twice. The organic layer was extracted with 6N HCl twice. The aqueous layer was neutralized and extracted with dichloromethane. The organic layer was dried over magnesium sulfate. The organic layer was concentrated with rotary evaporator and purified with silica gel column chromatography (eluent: dichloromethane/ethanol). The fraction was concentrated with rotary evaporator and recrystallized from cyclohexane. The peak at m/z=356([M+1]⁺) was observed in FAB-MS. Yield: 0.36 g (11.5%).

### (IV-1′) Synthesis of mdppy (The Method Using Chlorodiphenylphosphine)

### (IV-1′-1) Synthesis of 3-bromodiphenylphosphine oxide (mBrdppo)

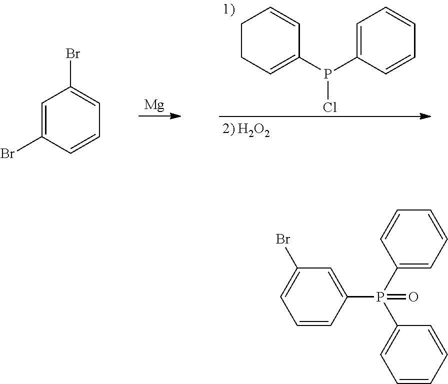

To 2.16 g (88.9 mmol) of magnesium, 5 mL of THF was added, then a THF solution of 17.5 g of 1,3-dibromobenzene (74.1 mmol) was added dropwise at 0° C. The mixture was stirred until all magnesium was consumed, then 40 mL of THF was added and the mixture was stirred for 1 hour. The mixture was cooled to 0° C. and 15.7 mL of chlorodiphenylphosphine (84.5 mmol) was added dropwise. The mixture was stirred overnight at room temperature. After the reaction completed, 1 N HCl was added to hydrolyze. The mixture was extracted with dichloromethane and the organic layer was dried over magnesium sulfate. The organic layer was concentrated with rotary evaporator, the residue was dissolved in chloroform (containing amylene), 30% hydrogen peroxide was added slowly with cooling and the mixture was stirred overnight. The mixture was washed with water and saturated sodium hydrogensulfite and extracted with dichloromethane. The organic layer was dried over magnesium sulfate. The residue was purified with silica gel column chromatography (eluent: dichloromethane/ethanol). The fraction was concentrated and recrystallized from cyclohexane. The peak at m/z=357([M]⁺) was observed in FAB-MS. Yield: 4.84 g (18.3%).

### (IV-1′-2) Synthesis of 2-[(3-diphenylphosphoryl)phenyl]pyridine (mdppy)

Synthesized similarly to (IV-1-2).

### (IV-1″) Synthesis of mdppy (The Method Using Suzuki-Coupling)

### (IV-1″-1) Synthesis of 2-(3-bromophenyl)pyridine (2(3BrPh)py)

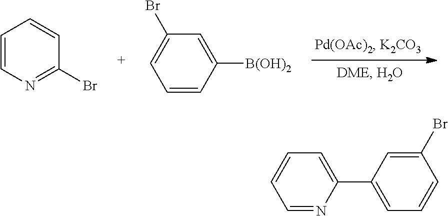

To 1.82 g of 2-bromopyridine (11.5 mmol), 1.54 g of 3-bromophenylboronic acid (7.68 mmol), 0.043 g of palladium acetate (Pd(OAc)₂) (0.19 mmol), 2.93 g of potassium carbonate (21.2 mmol) and 0.20 g of triphenylphosphine (0.78 mmol), 16 mL of 1,2-dimethoxyethane of 9.6 mL of water were added and reacted overnight. After the reaction completed, the mixture was extracted with dichloromethane twice. Then the organic layer was extracted with 6N HCl twice. The aqueous layer was neutralized and extracted with dichloromethane three times. The organic layer was dried over magnesium sulfate. The organic layer was concentrated and purified with silica gel column chromatography (eluent: dichloromethane). The fraction was concentrated. The peak at m/z=235 ([M+1]⁺) was observed in FAB-MS. The crude product was used for next reaction although it was considered to contain solvent and the like. Crude yield: 1.88 g (104%).

### (IV-1″-2) Synthesis of 2-(3-diphenylphosphoryl)pyridine (mdppy)

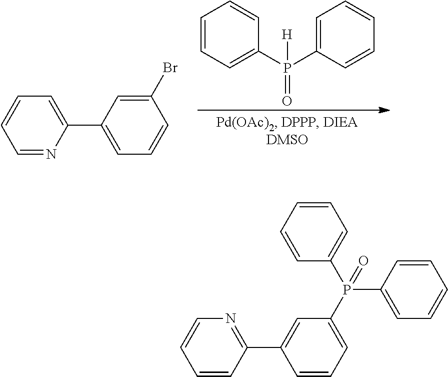

To 1.8 g of (2(3BrPh)Py) (synthesized according to IV-1″-1) (7.68 mmol), 1.86 g of diphenylphosphine oxide (9.2 mmol), 0.12 g of Pd(OAc)₂ (0.54 mmol) and 0.32 g of 1,3-diphenylphosphinopropane (DPPP) (0.77 mmol), 19 mL of DMSO was added and the mixture was stirred. 7.29 mL of N-ethyldiisopropylamine (DIEA) (42.6 mmol) was added and the mixture was reacted overnight at 100° C. After the reaction completed, the mixture was extracted with dichloromethane. Then the organic layer with 6N HCl twice. The aqueous layer was neutralized and extracted with dichloromethane three times. The organic layer was dried over magnesium sulfate. The organic layer was concentrated and purified with silica gel column chromatography (eluent: dichloromethane/ethanol) followed by the recrystallization from cyclohexane. The peak at m/z=356([M+1]⁺) was observed in FAB-MS. Yield: 0.77 g (28.3%).

### (IV-2) Synthesis of [bis(2-phenylpyridinato-N,C^{2′})-mono(2-(3-diphenylphosphoryl phenyl)pyridinato-N,C^{2′})]iridium(III) (Ir(ppy)₂(mdppy))

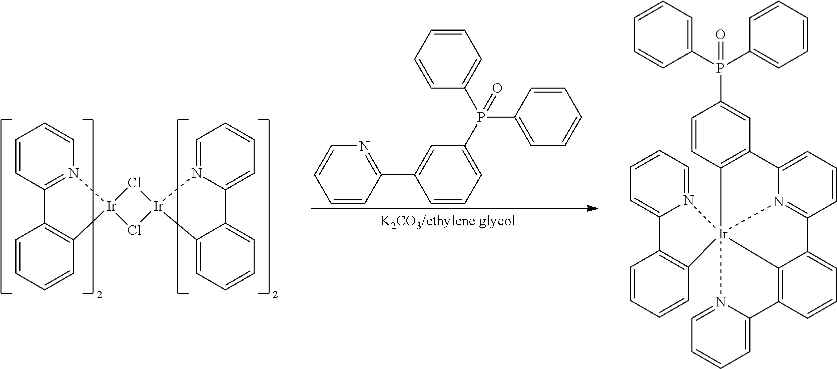

To 0.43 g of [Ir(ppy)₂Cl]₂ (synthesized according to 1-3) (0.4 mmol), 0.4 g of mdppy (synthesized according to IV-1) (1.1 mmol) and 0.29 g of potassium carbonate (2.1 mmol), 1 mL of ethyleneglycol was added and the mixture was refluxed overnight. After the reaction completed, dichloromethane was added and the mixture was filtrated with Celite. The filtrate was concentrated and purified with silica gel column chromatography (eluent: dichloromethane/ethanol). The peak at m/z=855([M]⁺) was observed in FAB-MS. Crude yield: 0.33 g (48.5%).

### [V] Synthesis of tris[(1-(4-diphenylphosphoryl)isoquinolinato-N,C^{2′})]iridium (III) (Ir(pdpiq)₃)

### (V-1) Synthesis of 1-(4-diphenylphosphine oxide)isoquinoline (pdpiq)

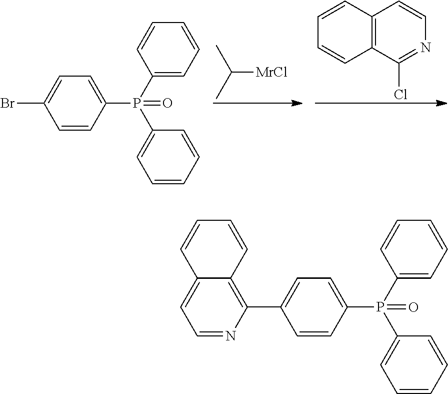

To a THF solution (30 mL) of 4-bromophenyldiphenylphosphine oxide (10.7 g, 30 mmol), 17 mL of a solution of isopropylmagnesium chloride (iPrMgCl) (2 M diethyl ether solution, 34 mmol) was added dropwise at room temperature and the mixture was stirred for 2 hours. 5.89 g of 1-chloroisoquinoline (36 mmol) and 0.54 g of [1,3-bis(diphenylphosphino)propane] dichloronickel(II) (Ni(dppp)Cl₂) (1 mmol) were added and the mixture was refluxed for 48 hours. After the reaction completed, the reaction mixture was quenched with saturated aqueous solution of ammonium chloride added. The mixture was extracted with dichloromethane. The organic layer was extracted with 6N HCl twice. The aqueous layer was neutralized and extracted with dichloromethane. The organic layer was dried over magnesium sulfate. The organic layer was concentrated and purified with silica gel column chromatography (eluent: dichloromethane/ethanol). The peak at m/z=406([M]⁺) was observed in FAB-MS. Recrystallized from cyclohexane. Yield: 2.30 g (18.8%).

### (V-2) Synthesis of tetrakis(1-(4-diphenylphosphoryl)isoquinolinato-N,C^{2′}) (μ-dichloro)diiridium(III) ([Ir(pdpiq)₂Cl]₂)

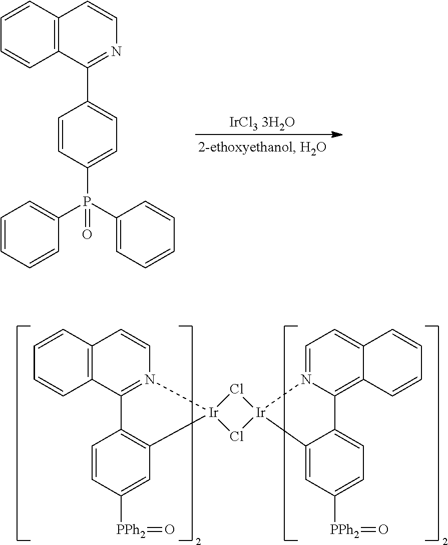

To 1.3 g of pdpiq (synthesized according to V-1) (3.2 mmol) and 0.42 g of iridium chloride (1.2 mmol), 20 mL of 2-ethoxyethanol and 6 mL of water were added and the mixture was refluxed while being stirred overnight. After the reaction completed, the mixture was cooled to room temperature and water was added to precipitate the product. The precipitate was filtrated, washed with water and dried. Yield: 1.24 g (100%).

### (V-3) Synthesis of bis(acetonitrile)bis[(1-(4-diphenylphosphoryl)isoquinolinato-N,C^{2′})] iridium(III) tetrafluoroborate (Ir(dppiq)₂(CH₃CN)₂BF₄)

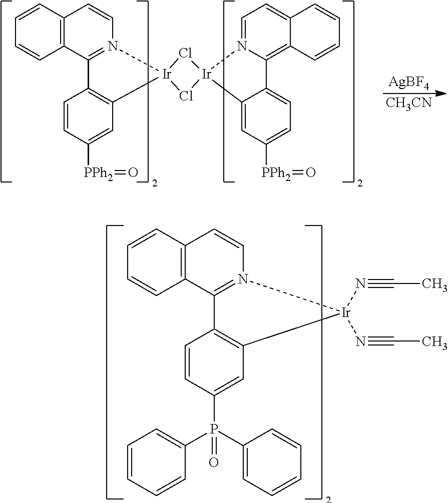

To 1.24 g of [Ir(dpiq)₂Cl]₂ (synthesized according to V-2)(0.60 mmol) and 0.26 g of silver tetrafluoroborate (1.35 mmol), 34 mL of acetonitrile was added and the mixture was refluxed for 6 hours. After the reaction completed, white precipitate was removed by filtration and the filtrate was concentrated with rotary evaporator. Yield: 1.37 g (98.6%).

### (V-4) Synthesis of tris[(1-(4-diphenylphosphoryl)isoquinolinato-N,C^{2′})]iridium (III) (Ir(pdpiq)₃)

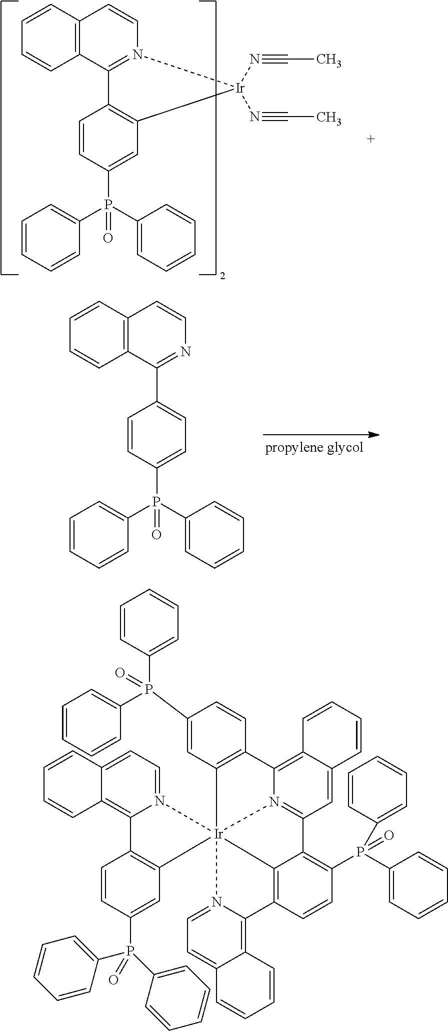

To 1.33 g of [Ir(piq)₂(CH₃CN)₂]BF₄ (synthesized according to V-3) (1.14 mmol) and 1.38 g of pdpiq (synthesized according V-1) (3.4 mmol), 40 mL of propyleneglycol was added and reacted at 160° C. After the reaction completed, the mixture was extracted with dichloromethane and the organic layer was dried over magnesium sulfate. The solution was concentrated with rotary evaporator and the residue was purified with silicagel column chromatography (eluent: dichloromethane/ethanol). The peak at m/z=1408([M+3]⁺) was observed in FAB-MS. Crude yield: 1.25 g (78.1%).

### [VI] Synthesis of tris[(1-(3-diphenylphosphoryl)isoquinolinato-N,C^{2′})]iridium (III) (Ir(mdpiq)₃)

### (VI-1) Synthesis of 1-(3-bromophenyl)isoquinoline (mBrpiq)

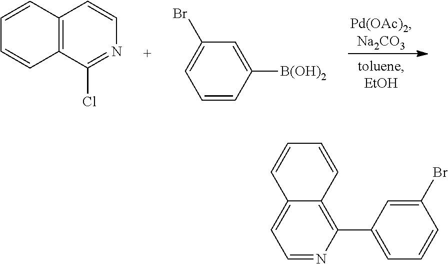

To 1.83 g of 3-bromophenylboronic acid (15 mmol) and 3.69 g of 1-chloroisoquinoline (22.5 mmol), 15 mL of toluene, 75 mL of ethanol and 15 mL of 2 M sodium carbonate solution were added and the mixture was stirred under argon stream. 0.63 g of Pd(PPh₃)₄ (0.55 mmol) was added and the mixture was refluxed and stirred overnight. After the reaction completed, the mixture was cooled to room temperature, then water and toluene were added and the mixture was extracted. The organic layer was washed with brine and dried over magnesium sulfate. The crude product was purified with silicagel column chromatography (eluent: dichloromethane). The peak at m/z=206([M]⁺) was observed in FAB-MS. Crude yield: 3.04 g (71.4%).

### (VI-2) Synthesis of 1-(3-diphenylphosphorylphenyl)isoquinoline (mdpiq)

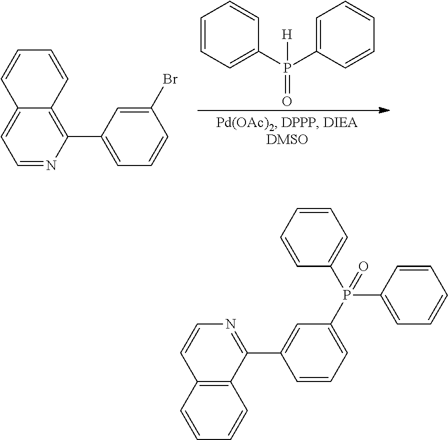

To 0.85 g of mBrpiq (synthesized according to VI-1) (7.63 mmol), 1 g of DPPO (4.9 mmol), 0.054 g of Pd(OAc)₂ (0.24 mmol) and 0.16 g of DPPP (0.39 mmol), 9 mL of DMSO was added and the mixture was stirred. 2.24 mL of DIEA (13.1 mmol) was added and the mixture was refluxed overnight. After the reaction completed, the mixture was extracted with dichloromethane. Then the organic layer was extracted with 6N HCl twice. The aqueous layer was neutralized and extracted with dichloromethane. The organic layer was dried over magnesium sulfate. The organic layer was concentrated with rotary evaporator. The peak at m/z=406([M]⁺) was observed in FAB-MS. Crude yield: 1.11 g (91.0%).

### (VI-3) Synthesis of tetrakis(1-(3-diphenylphosphoryl)isoquinolinato-N,C^{2′}) (μ-dichloro)diiridium(III) ([Ir(mdpiq)₂Cl]₂)

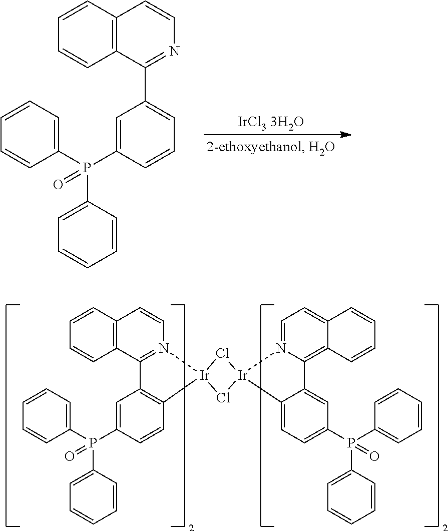

To 0.75 g of mdpiq (synthesized according to VI-2) (1.85 mmol) and 0.21 g of iridium chloride (0.6 mmol), 10 mL of 2-ethoxyethanol and 3 mL of water were added and the mixture was refluxed overnight. After the reaction completed, the mixture was cooled to room temperature and water was added to precipitate the product. The precipitate was filtrated and dried. The peak at m/z=1001 ([(M-Cl)/2]⁺) was observed in FAB-MS. Crude yield: 0.56 g (90.8%).

### (VI-4) Synthesis of bis(acetonitrile)bis[(2-(3-diphenylphosphinophenyl) isoquinolinato-N,C^{2′})iridium(III)tetrafluoroborate Ir(mdpiq)₂(CH₃CN)₂BF₄)

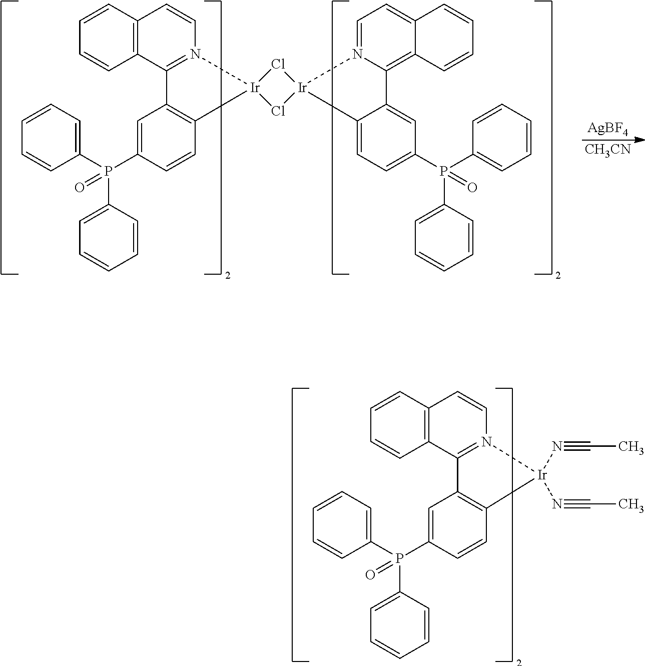

To 0.56 g of [Ir(mdpiq)₂Cl]₂ (synthesized according to VI-3) (0.27 mmol) and 0.12 g of silver tetrafluoroborate (0.62 mmol), 15 mL of acetonitrile was added and the mixture was refluxed for 4 hours. After the reaction completed, white precipitate was removed by filtration and the filtrate was concentrated with rotary evaporator. As the crude product contained solvent, crude yield exceeded 100%. It was used without further purification assuming the yield of 100%.

### (VI-5) Synthesis of tris[(1-(3-diphenylphosphoryl)isoquinolinato-N,C^{2′})]iridium (III) (Ir(mdpiq)₃)

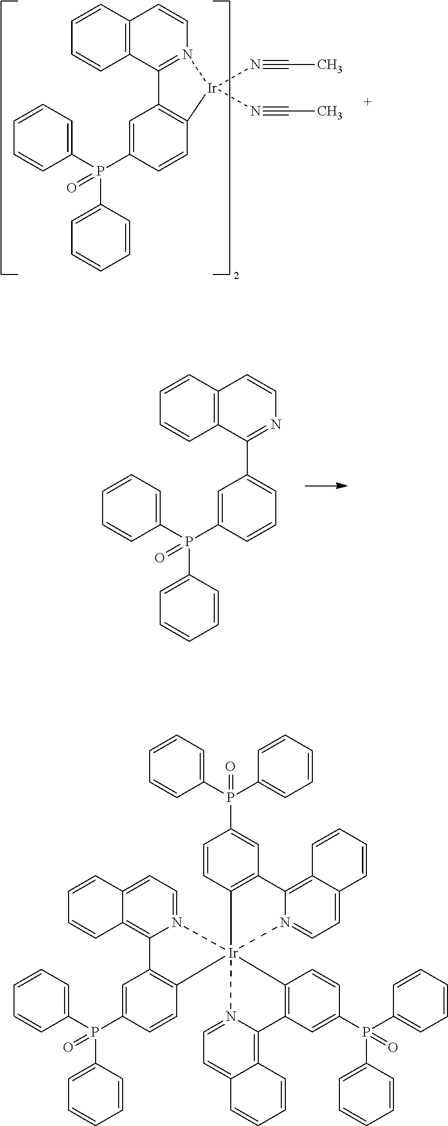

To 0.63 g of [Ir(mdpiq)₂(CH₃CN)₂]BF₄ (synthesized according to VI-4) (0.54 mmol) and 0.64 g of mdpiq (synthesized according VI-2) (1.6 mmol), 17 mL of propyleneglycol was added and refluxed for 5 hours. After the reaction completed, the mixture was extracted with dichloromethane. The solution was concentrated with rotary evaporator and the residue was purified with silicagel column chromatography (eluent: dichloromethane/ethanol). The peak at m/z=1409([M+4]⁺) was observed in FAB-MS. Crude yield: 0.65 g (85.6%).

### [VII] Synthesis of [(bis(2-(4-diphenylphosphinophenyl)pyridinatoN,C^{2′})-mono (1-phenylisoquinolinatoN,C^{2′}))iridium (Ir(pdppy)₂(piq))

### (VII-1) Synthesis of 1-phenylisoquinoline

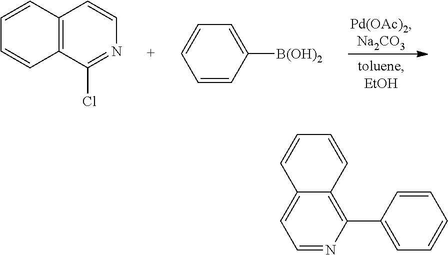

To 1.83 g of phenylboronic acid (15 mmol) and 2.44 g of 1-chloroisoquinoline (15 mmol), 15 mL of toluene, 7.5 mL of ethanol and 15 mL of 2 M Na₂CO₃ solution were added and the mixture was stirred under argon stream. 0.59 g of Pd(PPh₃)₄ (0.51 mmol) was added and the mixture was refluxed and stirred overnight. After the reaction completed, the mixture was cooled to room temperature and water and toluene were added and the mixture was extracted. The organic layer was washed with brine and dried over magnesium sulfate. The crude product was purified with silicagel column chromatography (eluent: dichloromethane). The peak at m/z=206([M]⁺) was observed in FAB-MS. Yield: 2.59 g (84.1%).

### (VII-2) Synthesis of tetrakis(2-(4-diphenylphosphorylphenyl)pyridinato-N,C^{2′}) (μ-dichloro)diiridium(III) ([Ir(pdppy)₂Cl]₂)

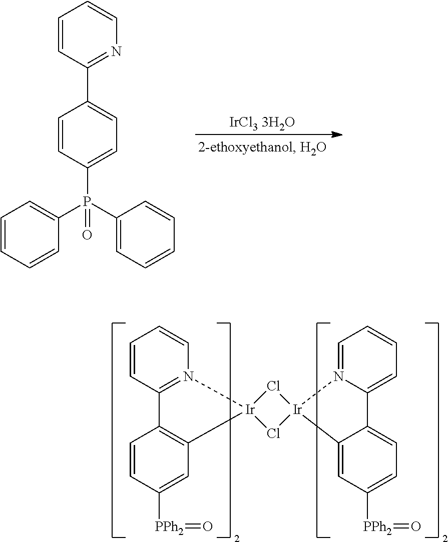

To 0.4 g of pdppy (synthesized according to 1-2) (1.13 mmol) and 0.16 g of iridium chloride hydrate (0.46 mmol), 6.8 mL of 2-ethoxyethanol and 2 mL of water were added and the mixture was refluxed and stirred overnight. After the reaction completed, water was added and the precipitate formed was filtrated and washed with water. Product was confirmed by FAB-MS (m/z=901[(M-Cl)/2]⁺, 937([M/2]⁺). Yield: 0.42 g (98.5%).

### (VII-3) Synthesis of bis(acetonitrile)bis[(2-(4-diphenylphosphinophenyl)pyridinato-N,C^{2′})]iridium(I II) tetrafluoroborate (Ir(pdppy)₂(CH₃CN)₂BF₄)

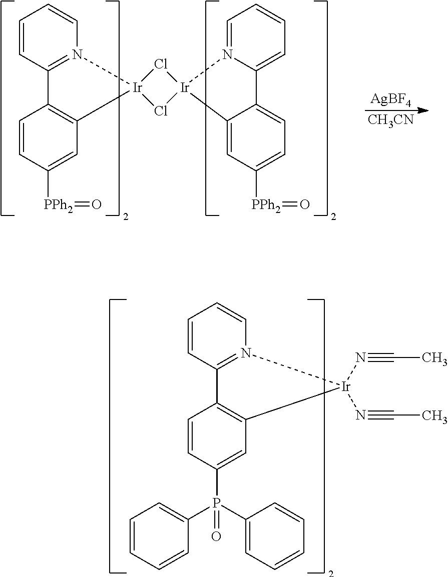

To 0.21 g of [Ir(pdppy)₂Cl]₂ (synthesized according to VII-2) (0.12 mmol) and 0.05 g of silver tetrafluoroborate (0.26 mmol), 7 mL of acetonitrile was added and the mixture was refluxed for 4 hours. After cooling, white precipitate was removed by filtration and the filtrate was concentrated with rotary evaporator. The peaks at m/z=901([M-BF₄-2CH₃CN]⁺) and 942([M-BF₄—CH₃CN]⁺) were observed in FAB-MS.

### (VII-4) Synthesis of [(bis(2-(4-diphenylphosphinophenyl)pyridinatoN,C^{2′})-mono (1-phenylisoquinolinatoN,C^{2′}))iridium (Ir(pdppy)₂(piq))

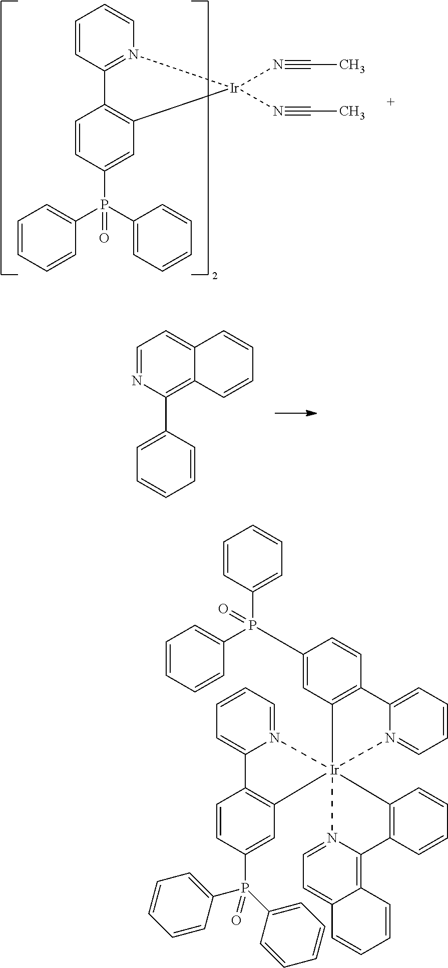

To 0.16 g of Ir(pdppy)₂(CH₃CN)₂BF₄ (synthesized according to VII-3) (0.15 mmol) and 0.09 g of 1-phenylisoquinoline (synthesized according VII-1) (0.43 mmol), 5 mL of propyleneglycol was added and reacted at 160° C. After the reaction completed, the mixture was extracted with dichloromethane and the organic layer was dried over magnesium sulfate. The solution was concentrated with rotary evaporator and the residue was purified with silicagel column chromatography (eluent: dichloromethane/ethanol). The peak at m/z=1105([M]⁺) was observed in FAB-MS. Crude yield: 60 mg (24.0%).

### (3) Investigation on the Condition of Isomerization to fac-Isomer

Condition of the isomeriazation of mer-isomer of iridium complex to fac-isomer by UV irradiation was investigated using Ir(ppy)₂(pdppy) synthesized according to [I] of (2) as described above. The ratio of the isomers fac-:mer- before isomerization was determined using reverse-phase HPLC (YMC-Pack ODS-AQ: φ50×500 mm, H₂O:MeOH=20:80) to be 45:55. Irradiation using high-pressure mercury lump (Orc Manufacturing Co. Ltd., HANDY UV 500:500 W) in various solvents showed that complete isomerization to fac-isomer was observed by irradiating for 3 hours in THF solution (57.2 mg/40 mL), which was confirmed by reverse-phase HPLC analysis.

### [VIII] Synthesis of [bis(2-(4-diphenylphosphorylphenyl)pyridinato-N,C^{2′}) (acetylacetonato)]iridium(III) (Ir(pdppy)₂(acac))

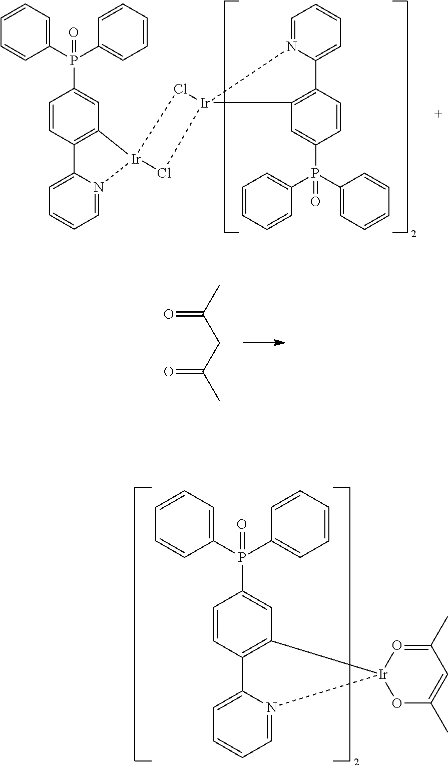

To 1.05 g of [Ir(pdppy)₂Cl]₂ (synthesized according to II-1) (1.13 mmol), 1.8 mL of acetylacetone (18 mmol) and 0.72 g of sodium carbonate (6.8 mmol), 18 mL of 2-ethoxyethanol was added and the mixture was heated and stirred at 80° C. for 1.5 hours. After the reaction completed, the mixture was extracted with dichloromethane and the aqueous layer was also extracted with dichloromethane. The organic layer was combined and dried over magnesium sulfate. After concentration, the residue was purified with silicagel column chromatography (eluent: dichloromethane/ethanol). Recrystallized from toluene/ethanol. Yield: 0.178 g (26.6%).

### [IX] Synthesis of [bis(1-(4-(diphenylphosphoryl)phenyl)isoquinolinato-N,C^{2′}) (acetylacetonato)]iridium(III) (Ir(pdpiq)₂(acac))

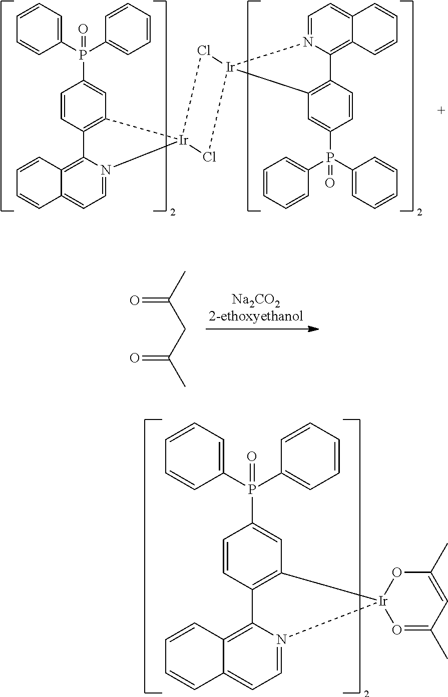

To 0.3 g of [Ir(pdpiq)₂Cl]₂ (synthesized according to V-2) (0.15 mmol), 0.08 mL of acetylacetone (0.8 mmol) and 0.32 g of sodium carbonate (3.0 mmol), 8 mL of 2-ethoxyethanol was added and the mixture was stirred at room temperature for 1 hour and refluxed overnight. After the reaction completed, the mixture was cooled to room temperature and extracted with dichloromethane and the aqueous layer was also extracted with dichloromethane. The organic layer was combined and washed with saturated aqueous solution of sodium chloride, then dried over magnesium sulfate. After concentration with rotary evaporator, the residue was purified with silicagel column chromatography (eluent: dichloromethane/ethanol). The peak at m/z=1101 ([M+1]⁺) was observed in FAB-MS. Crude yield: 0.15 g (45.5%).

### [X] Synthesis of [bis(1-(4-diphenylphosphoryl)phenyl)isoquinolinato-N,C^{2′}) (2,2,6,6-tetramethyl-3,5-heptanedionato)]iridium(III) (Ir(pdpiq)₂(TMHD))

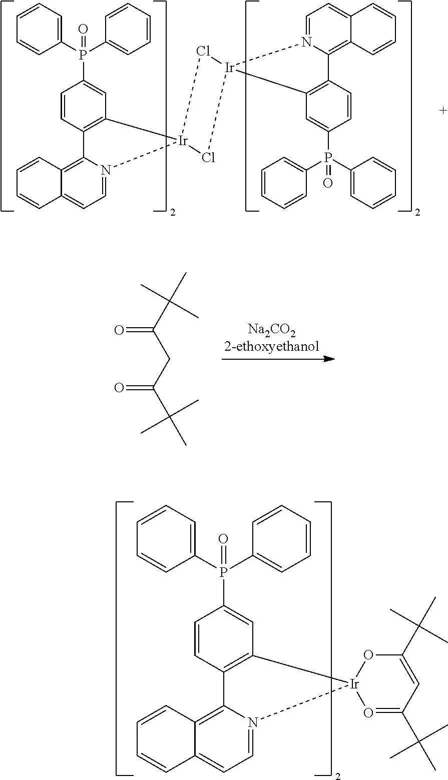

To 0.3 g of [Ir(pdpiq)₂Cl]₂ (synthesized according to V-2) (0.15 mmol), 0.16 mL of 2,2,6,6-tetramethyl-3,5,-heptanedione (0.8 mmol) and 0.32 g of sodium carbonate (3.0 mmol), 8 mL of 2-ethoxyethanol was added and the mixture was stirred at room temperature for 1 hour and refluxed overnight. After the reaction completed, the mixture was cooled to room temperature and extracted with dichloromethane and the aqueous layer was also extracted with dichloromethane. The organic layer was combined and washed with saturated aqueous solution of sodium chloride, then dried over magnesium sulfate. After concentration with rotary evaporator, the residue was purified with silicagel column chromatography (eluent: dichloromethane/ethanol). The peak at m/z=1184([M]⁺) was observed in FAB-MS. Crude yield: 0.39 g (109%).

### [XI] Synthesis of [bis(1-(4-(diphenylphosphoryl)phenyl)isoquinolinato-N,C^{2′}) (1,3-diphenyl-1,3-propanedionato)]iridium(III) (Ir(pdpiq)₂(DBM))

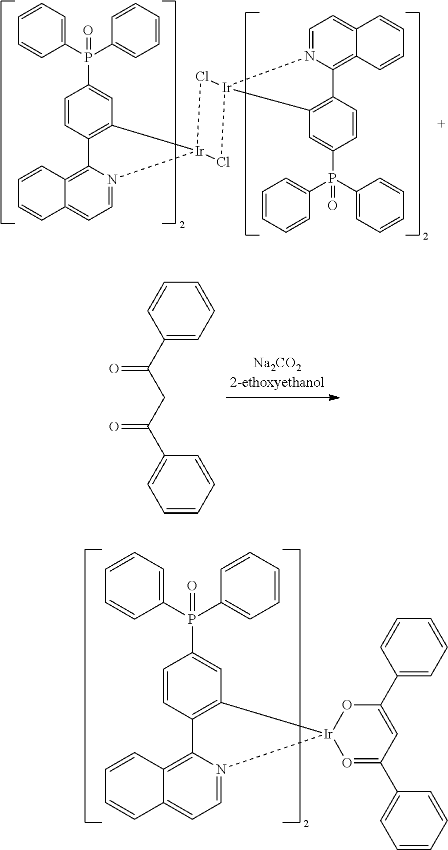

To 0.3 g of [Ir(pdpiq)₂Cl]₂ (synthesized according to V-2) (0.15 mmol), 0.18 g of 1,3-diphenylpropane-1,3,-dione (0.8 mmol) and 0.32 g of sodium carbonate (3.0 mmol), 8 mL of 2-ethoxyethanol was added and the mixture was heated and stirred at room temperature for 1 hour and refluxed overnight. After the reaction completed, the mixture was cooled to room temperature, extracted with dichloromethane and the aqueous layer was also extracted with dichloromethane. The organic layer was combined washed with saturated aqueous solution of sodium chloride, then and dried over magnesium sulfate. After concentration with rotary evaporator, the residue was purified with silicagel column chromatography (eluent: dichloromethane/ethanol). The peak at m/z=1225 ([M+1]⁺) was observed in FAB-MS. Crude yield: 0.24 g (65.4%).

### [XII] Synthesis of [bis(1-(4-(diphenylphosphoryl)phenyl)isoquinolinato-N,C^{2′}) (1,3-diphenyl-1,3-propanedionato)]iridium(III) (Ir(pdpiq)₂(TFA))

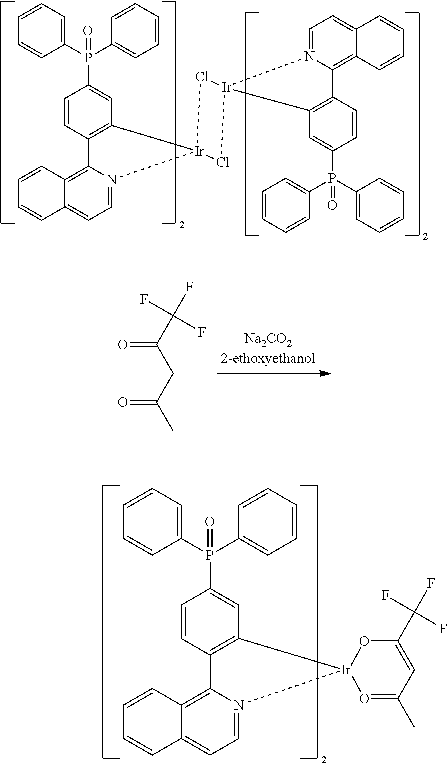

To 0.3 g of [Ir(pdpiq)₂Cl]₂ (synthesized according to V-2) (0.15 mmol), 0.096 mL of trifluoroacetylacetone (0.8 mmol) and 0.32 g of sodium carbonate (3.0 mmol), 8 mL of 2-ethoxyethanol was added and the mixture was stirred at room temperature for 1 hour and refluxed overnight. After the reaction completed, the mixture was cooled to room temperature, extracted with dichloromethane and the aqueous layer was also extracted with dichloromethane. The organic layer was combined and washed with saturated aqueous solution of sodium chloride, then dried over magnesium sulfate. After concentration with rotary evaporator, the residue was purified with silicagel column chromatography (eluent: dichloromethane/ethanol). The peak at m/z=1155 ([M+1]⁺) was observed in FAB-MS. Crude yield: 0.23 g (66.5%).

### [XIII] Synthesis of [tris(3-diphenylphosphorylphenylimidazo[1,2-f]phenanthridinato-N,C^{2′})]iridium(III) Ir(3dpoipt)₃

### [XIII-1] Synthesis of phenanthridine-6-amine

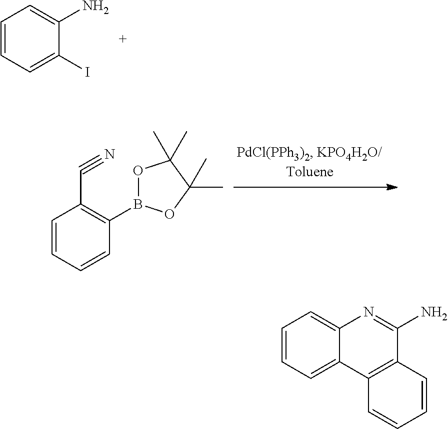

To 3.42 g of 2-iodoaniline (15.6 mmol), 4.31 g of 2-cyanophenylboronic acid pinacol ester (18.8 mmol), 0.56 g of dichlorobis(triphenylphosphine)palladium (0.8 mmol) and 7.39 g of tripotassium phosphate monohydrate (32 mmol), 65 mL of toluene was added and the mixture was refluxed for 4 hours. The mixture was cooled to room temperature and the precipitate formed was filtered off. The precipitate was washed with toluene and water. The peak at m/z=195([M+1]⁺) was observed in FAB-MS. Crude yield: 2.21 g (73%).

### [XIII-2] Synthesis of imidazo[1,2-f]phenanthridine

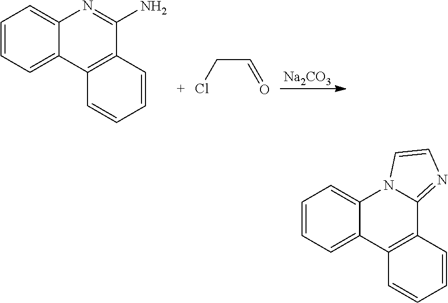

To 2.2 g of phenanthridine-6-amine (synthesized according to XIII-1) (11.3 mmol), 1.96 g of chloroacetoaldehyde (10 mmol) and 1.76 g of sodium carbonate (16.6 mmol), 33 mL of 2-propanol was added and the mixture was stirred at 80° C. for 2 hours. After the reaction completed, solvent was removed by rotary evaporator and the residue was extracted with dichloromethane. The crude product was purified with silicagel column chromatography (eluent: dichloromethane/ethanol). The peak at m/z=219([M+1]⁺) was observed in FAB-MS. Crude yield: 1.29 g (52.4%).

### [XIII-3] Synthesis of 3-(diphenylphosphoryl)phenylimidazo[1,2-f]phenanthridine (3dpoipt)

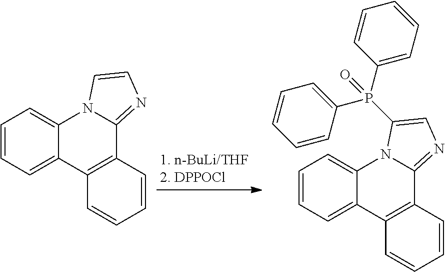

To 2.09 g of imidazo[1,2-f]imidazophenanthridine (synthesized according to XIII-2) (9.6 mmol), 20 mL of THF was added at the temperature below −80° C. under argon atmosphere. 14.5 mL of n-butyllithium solution (1.6 M in hexane) (23.2 mmol) was slowly added dropwise and the mixture was stirred for 3 hours. 5.68 g of diphenylphosphoryl chloride (24 mmol) was added dropwise and the mixture was for 1 hour. The mixture was slowly brought to room temperature and stirred overnight. After the reaction completed, saturated aqueous solution of ammonium chloride was added to the mixture, extracted with dichloromethane. The organic layer was dried over magnesium sulfate and concentrated with rotary evaporator. The peak at m/z=419 ([M]⁺) was observed in FAB-MS. Purification was carried out by silicagel column chromatography (eluent: dichloromethane/ethanol). The product was washed with small amount of dichloromethane. Yield: 3.18 g (79.1%).

### [XIII-4] Synthesis of [tetrakis(3-(diphenylphosphoryl)phenylimidazo[1,2-f]phenanthridinato-N,C^{2′})](μ-dichloro)diiridium(III) ([Ir(3dpoipt)₂Cl]₂)

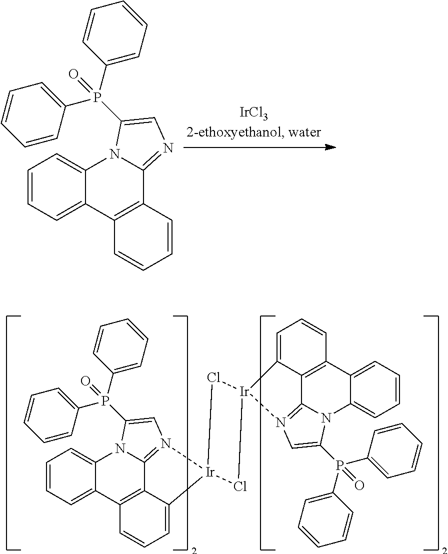

To 1.67 g of 3dpoipt (synthesized according to XIII-3) (4 mmol) and 0.53 g of iridium chloride hydrate (1.5 mmol), 25 mL of 2-ethoxyethanol and 7.5 mL of water were added and the mixture was refluxed overnight. After the reaction completed, the mixture was cooled to room temperature and the precipitate formed was collected by filtration and washed with water. The peaks at m/z=1027 ([(M-Cl)/2]+) and 1062 ([M/2−1]⁺) were observed in FAB-MS. Crude yield: 1.18 g (37%).

### [XIII-5] Synthesis of bis[(3-(diphenylphosphoryl)phenylimidazo[1,2-f]phenanthridinato-N,C^{2′})](acetylacetonato)iridium(III) (Ir(3dpoipt)₂(acac))

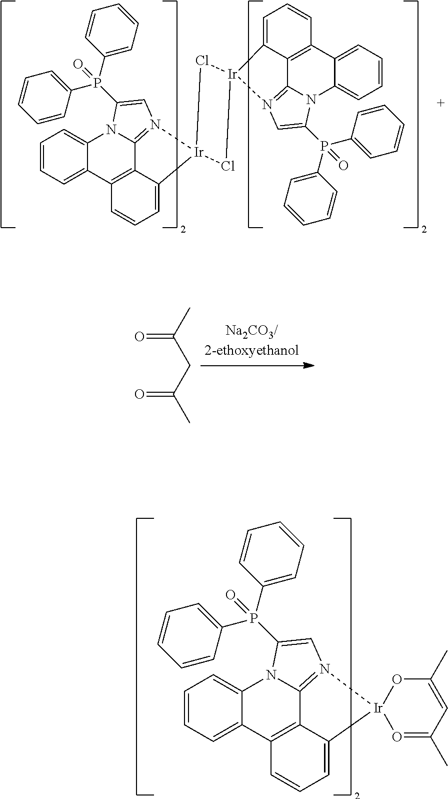

To 0.79 g of [Ir(3dpoipt)₂Cl]₂ (synthesized according to XIII-4) (0.33 mmol), 0.18 mL of acetylacetone (1.8 mmol) and 0.73 g of sodium carbonate (6.8 mmol), 18 mL of 2-ethoxyethanol was added and the mixture was stirred and refluxed for 1.5 hours. After the reaction completed, methanol was added and the precipitate formed was filtered off (filtrate 1), then the precipitate was washed with water (precipitate). FAB-MS results showed that both of the filtrate 1 and the precipitate contained the product (m/z=1127 ([M+1]⁺)). The filtrate and the precipitate were combined and purified with silicagel column chromatography (eluent: dichloromethane/ethanol). Yield: 0.56 g (76%).

[XIII-6] Synthesis of [tris(3-diphenylphosphorylphenylimidazo[1,2-f]phenanthridinato-N,C^{2′})]iridium(III) (Ir(3dpoipt)₃

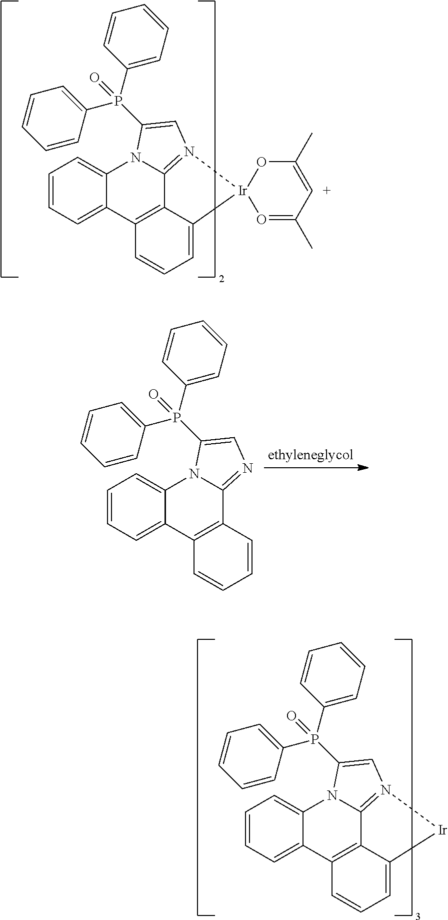

To 0.56 g of Ir(3dpoipt)₂(acac) (synthesized according to XIII-5) (0.50 mmol) and 0.69 g of 3dpiopt (1.65 mmol), 40 mL of ethyleneglycol was added and the mixture was heated and stirred at 150° C. for 1 hour, and at 170° C. for 2.5 hours. After the reaction completed, the mixture was extracted with dichloromethane/water and the organic layer was dried over magnesium sulfate. The organic layer was concentrated with rotary evaporator and the peaks at m/z=1446 ([M+2]⁺) and 1447 ([M+3]⁺) were observed in FAB-MS. The crude product was purified with silicagel column chromatography (eluent: dichloromethane/ethanol). Crude yield: 0.69 g (96%).

### [XIV] Synthesis of [tris(1-(3-diphenylphosphoryl)-3-methyl-benzimidazolene-C,C^{2′})]iridium(III) (Ir(mdpopmbiz)₃)

### [XIV-1] Synthesis of 3-diphenylphosphorylfluorobenzene (mFDPPOPh)

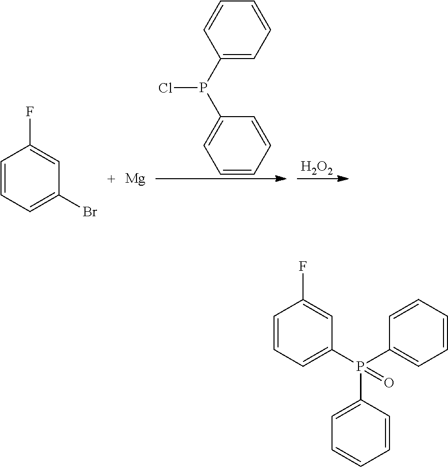

To 1.10 g (45.3 mmol) of magnesium, 20 mL of THF was added, cooled to 0° C. and a THF solution (20 mL) of 5.1 mL of 3-bromofluorobenzene (46.6 mmol) was added dropwise. After magnesium was almost consumed, the mixture was stirred at room temperature for 1 hour. The mixture was cooled to 0° C. and 7.58 mL of diphenylphosphinyl chloride (42.3 mmol) was added dropwise. The mixture was stirred overnight at room temperature. After the reaction completed, 1 N HCl was added to hydrolyze. The mixture was extracted with dichloromethane and the organic layer was dried over magnesium sulfate. The organic layer was concentrated with rotary evaporator. The product was dissolved in 40 mL of chloroform (containing amylene), 4.5 mL of 30% hydrogen peroxide (45 mmol) was added slowly with cooling and the mixture was stirred for 3 hours at room temperature. After the reaction completed, the mixture was washed with water and washed with saturated aqueous solution of sodium sulfite. The organic layer was dried over magnesium sulfate and concentrated with rotary evaporator. Recrystallized from cyclohexane/methanol. The peak at m/z=297([M+1]⁺) was observed in FAB-MS. Yield: 9.8 g (78.4%).

### [XIV-2] Synthesis of 1-(3-(diphenylphosphino)phenyl)-benzimidazole (mdpophbiz)

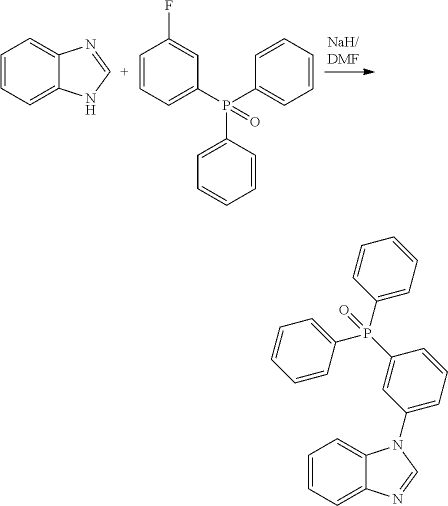

2.37 g of benzimidazole (20.1 mmol), 1.06 g of sodium hydride (55% parafin) (24.3 mmol) and 100 mL of DMF were placed under argon atmosphere and the mixture was stirred for 10 minutes. 5.93 g of mFDPPOPh (synthesized according to XIV-1) (20.0 mmol) was added and the mixture was heated to 100° C. and stirred for 18.5 hours. 0.48 g of sodium hydride (11.0 mmol) was added and the mixture was reacted at 130° C. overnight. After the reaction completed, the mixture was cooled to room temperature and poured onto ice. The mixture was extracted with dichloromethane. Saturated aqueous ammonium chloride solution was added to the organic layer and extracted with dichloromethane twice. The organic layer was dried over magnesium sulfate and concentrated with rotary evaporator. The crude product was purified with silicagel column chromatography (eluent: dichloromethane/ethanol). The peak at m/z=395([M−1]⁺) was observed in FAB-MS. Recrystallized from cyclohexane/ethanol. Yield: 2.82 g (35.6%).

### [XIV-3] Synthesis of 1-(3-(diphenylphosphoryl)phenyl)-3-methyl-benzimidazolium iodide (mdpophbiz-I)

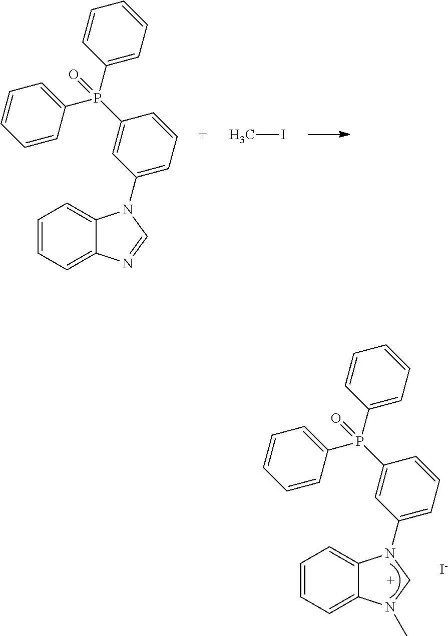

To 2.82 g of mdpophbiz (synthesized according to XIV-2), 40 mL of THF and heated to 60° C. to dissolve. 2.29 mL of iodomethane was added and the mixture was stirred overnight at room temperature. The mixture was concentrated with rotary evaporator and the residue was purified with silicagel column chromatography (eluent: dichloromethane/ethanol/methanol). The peak at m/z=409 ([M-I-1]⁺) was observed in FAB-MS. Crude yield: 1.36 g (35.7%).

### [XIV-4] Synthesis of [tris(1-(3-(diphenylphosphoryl)phenyl)-3-methyl-benzimidazolene-C,C^{2′})]iridium (Ir(mdpophbiz)₃)

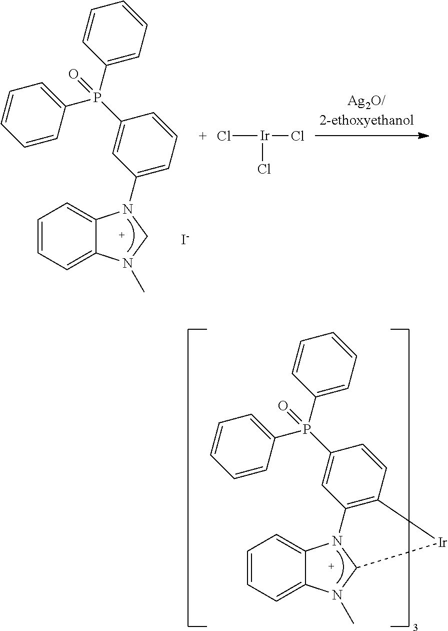

To 2.15 g of Mdpophbiz-I (synthesized according to XIV-3) (4.00 mmol), 0.33 g of iridium chloride (1.1 mmol) and 0.93 g of silver oxide (3.98 mmol), 84 mL of 2-ethoxyethanol was added. The mixture was reacted at 120° C. for 24 hours in a flask shaded with aluminum foil. After the reaction completed, solvent was removed with rotary evaporator to dryness and dichloromethane was added. Insoluble solid was filtered off with Celite and the filtrate was concentrated with rotary evaporator. The crude product was purified with silicagel column chromatography (eluent: dichloromethane/ethanol). The peak at m/z=1416 ([M+2]⁺) was observed in FAB-MS. Crude yield: 0.22 g (14.2%).

### [XV] Synthesis of [tris(1-(3-(diphenylphosphoryl)phenyl)-3-methyl-imidazolene-C,C^{2′})]iridium(III) Ir(mdpopmiz)₃

### [XV-1] Synthesis of 3-diphenylphosphorylfluorobenzene (mFDPPOPh)

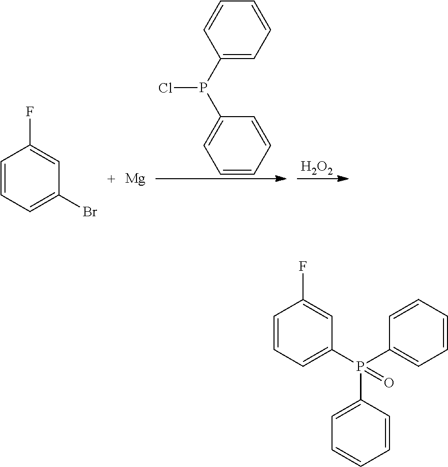

To 1.10 g (45.3 mmol) of magnesium, 20 mL of THF was added, cooled to 0° C. and a THF solution (20 mL) of 5.1 mL of 3-bromofluorobenzene (46.6 mmol) was added dropwise. After magnesium was almost consumed, the mixture was stirred at room temperature for 1 hour. The mixture was cooled to 0° C. and 7.58 mL of diphenylphosphinyl chloride (42.3 mmol) was added dropwise. The mixture was stirred overnight at room temperature. After the reaction completed, 1 N HCl was added to hydrolyze. The mixture was extracted with dichloromethane and the organic layer was dried over magnesium sulfate. The organic layer was concentrated with rotary evaporator. The product was dissolved in 40 mL of chloroform (containing amylene), 4.5 mL of 30% hydrogen peroxide (45 mmol) was added slowly with cooling and the mixture was stirred for 3 hours at room temperature. After the reaction completed, the mixture was washed with water and washed with saturated aqueous solution of sodium sulfite. The organic layer was dried over magnesium sulfate and concentrated with rotary evaporator. Recrystallized from cyclohexane/methanol. The peak at m/z=297([M+1]⁺) was observed in FAB-MS. Yield: 9.8 g (78.4%).

### [XV-2] Synthesis of 1-(3-(diphenylphosphoryl)phenyl)-imidazole

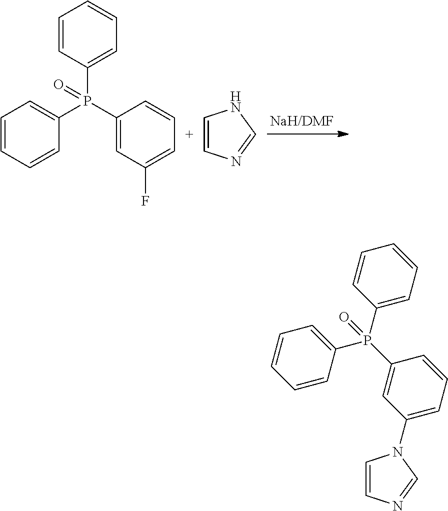

To a DMF solution (10 mL) of 0.13 g of imidazole (2.00 mmol), 0.097 g of sodium hydride (60% parafin) (2.42 mmol) was added under argon atmosphere and the mixture was stirred for 10 minutes. 0.60 g of mFDPPOPh (synthesized according to XV-1) (2.02 mmol) was added and the mixture was heated to 120° C. and stirred for 5 hours. After the reaction completed, water was added and the mixture was extracted with dichloromethane. The organic layer was dried over magnesium sulfate and concentrated. The peak at m/z=345([M+1]⁺) was observed in ASAP-TOF-MS. The crude product was purified with silicagel column chromatography (eluent: dichloromethane/ethanol). Crude yield: 0.53 g (51.5%).

### [XV-3] Synthesis of 1-(3-(diphenylphosphoryl)phenyl)-3-methyl-imidazolium iodide

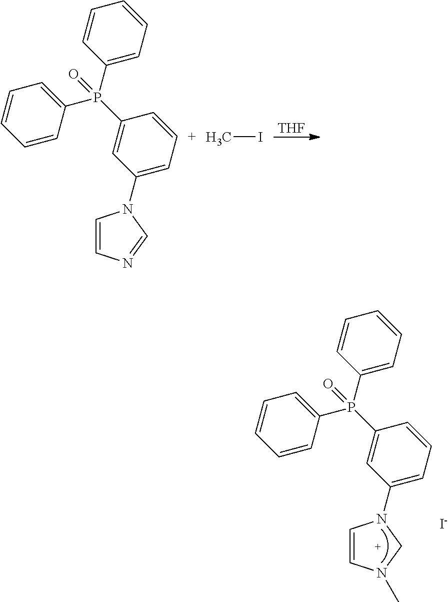

To 0.50 g of 1-(3-diphenylphosphoryl)-benzimidazole (synthesized according to XIV-2) (1.26 mmol) in 4 mL of THF, 0.36 mL of iodomethane (5.9 mmol) was added under argon atmosphere and the mixture was stirred overnight at room for 16 hours. After the reaction completed, the mixture was concentrated and the residue was purified with silicagel column chromatography (eluent: dichloromethane/ethanol/methanol). Crude yield: 0.67 g (95.7%).

### [XV-4] Synthesis of [tris(1-(3-(diphenylphosphoryl)phenyl)-3-methyl-imidazolene-C,C^{2′})]iridium (Ir(mdpophbiz)₃)

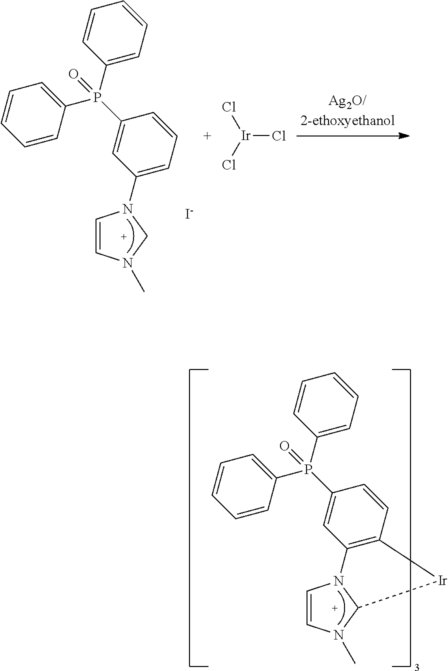

To 0.67 g of 1-(3-(diphenylphosphoryl)phenyl)-3-methyl-imidazolium iodide (synthesized according to XV-3), 0.12 g of iridium chloride (0.38 mmol) and 0.33 g of silver oxide(I) (1.38 mmol), 29 mL of 2-ethoxyethanol was added. The mixture was stirred at 120° C. for 22 hours in a shaded flask. After the reaction completed, the mixture was cooled to room temperature, dichloromethane was added and the mixture was filtrated with Celite. The filtrate was concentrated and the crude product was purified with silicagel column chromatography (eluent: dichloromethane/ethanol). The peaks at m/z=1265 ([M-4]⁺) and 907 ([M-ligand]⁺) were observed in FAB-MS.

### (4) Production of Laminated Organic EL Element (Organic Electroluminescent Element)

ITO on glass plate from Sanyo Vacuum Industries (80 nm thick) was used as a substrate. For washing the substrate, electronic grade 2-propanol from Kanto Chemical was used. Alcohol solvents from Kanto Chemicals, electronic grade toluene from Kanto Chemicals were used for forming an electron transport layer and an emissive layer, respectively. As a hole injection material, PEDOT-PSS (H. C. Starck, AI4083) was used as received. As a hole transport material, poly(N-vinylcarbazole) (PVK, Sigma Aldrich) was used as a toluene solution (5 g/L or 10 g/L). As a host material used for the emissive layer, the phosphine oxide derivative represented by Formula F shown above was used. As a guest material, various iridium complexes synthesized according to the method described in (2) above. The amount of the guest material added was 8.7 weight percent of that of the host material and 2-propanol solutions with the concentration of 10 g/L or 15 g/L in total were prepared.

As a pretreatment, the ITO substrate was washed by immersing in boiling 2-propanol for 5 minutes, putting in UV/03 cleaner immediately and treating with O₃ by irradiating with UV light for 15 minutes. Layers of PEDOT-PSS and PVK and the emissive layer were formed using a spin coater from MIKASA under N2 atmosphere with oxygen concentration of 1 to 3 ppm followed by drying under N2 atmosphere (in a grove box) or in vacuum.

Deposition of the cathode (Al, purity 99.999%) and the electron transport layer (LiF) were carried out using an ultra high vacuum evaporator having the chamber pressure of 8×10⁻⁴ Pa. Deposition rate was 0.1 Å/s for LiF and 10 Å/s for Al. Sealing of all elements were carried out under N2 atmosphere. After the deposition of the cathode completed, the element was immediately transferred to a grove box (Kyushu Keisokki, dew point of −60 to −70° C., oxygen concentration of less than 5 ppm) purged with nitrogen and sealed with a glass cap coated with drying agent Oledry (14 μl).

The structure of the element was similar to that of FIG. 1 except that an electron transport layer was situated between the cathode and the emissive layer. The thickness of each layer was as followings.

anode: ITO (80 nm)

hole injection layer: PEDOT-PSS (50 nm)

hole transport layer: PVK (15 or 30 nm)

emissive layer: (40 or 70 nm)

electron transport layer: LiF (0.2 nm)

cathode: Al (100 nm)

### (5) Characterization of the Element and the Materials

Among luminescent properties (quantum yields) of guest materials, relative fluorescence quantum yields (Φp) were estimated by UV-VIS absorption spectra and fluorescence spectra measured in solutions using 9,10-diphenylanthracene with Φp=1 as a standard. As phosphorescence was quenched by oxygen, spectra were measured after bubbling with argon for 5 minutes to remove oxygen.

Voltage-current-luminance properties of the EL elements produced were measured using ADVANTEST DC voltage current source/monitor (TR6143) by applying voltage of 0 to 20 V and currents were measured in each 0.2 V step. EL spectra were measured using spectroscopic detector of Hamamatsu Photonics multi-channel spectrometer (C7473).

An OLED luminant efficiency measurement system was used for measuring current efficiency η_{c} [cd/A].

Equivalent lifetime at 500 cd/m² of the elements driven continuously on constant current of 50 mA/m² was measured using a system of APEX. Comparison of all elements was based on the equivalent values of half-life at 500 cd/m² obtained by converting actual measured time when the luminance drops to half using 1.5 power law (shown below).

1.5 power law: T=(L₀/L)^{1.5}×T₁

In the equation shown above, L₀ is initial luminance [cd/m²], L is calculated luminance [cd/m²], T₁ is actual measured time when the luminance drops to half and T is half-life.

Relative quantum yields of Ir(ppy)₂(pdppy), Ir(ppy)(pdppy)₂ and Ir(pdppy)₃ relative to 9,10-diphenylanthracene were 0.35, 0.44 and 0.47, respectively. Relative quantum yield of Ir(ppy)₃ without phosphine oxide moiety was estimated to be 0.40 in a similar manner. From these results it was confirmed that the relative quantum yield increased with increasing the number of bulky phosphine oxide groups that prevent the aggregation of molecules.

Results of current efficiency η_{c}, equivalent lifetime at 500 cd/m² (lifetime relative to Example 11 using Ir(ppy)₃ that has no phosphine oxide moiety as the guest material) and luminescent color of Examples 1 to 13 are summarized in Table 1 (The host material, guest material, metal compounds used and their concentrations in each example are also shown). The structure of the guest material C545T used in Example 13 is shown below.

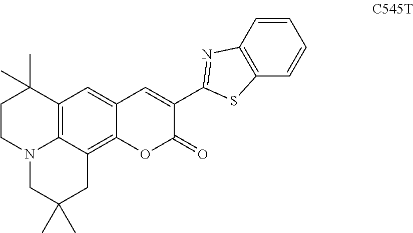

TABLE 1

| | | | Metal | | | |
|---|---|---|---|---|---|---|
| | | | compound- | Current | | |
| | | Guest- | Concen- | efficiency | Relative | |
| Ex. | Host | Concentration | tration | η_{c} | lifetime | Color |
| 1 | F | Ir(ppy)₂(pdppy)- | — | 67 cd/A | 52.0 | green |
| | | 8 wt % | | | | |
| 2 | F | Ir(ppy)₂(pdppy)- | Li(acac)- | 48 cd/A | 131.0 | green |
| | | 12 wt % | 8 wt % | | | |
| 3 | F | Ir(pdppy)₃- | — | 63 cd/A | 71.0 | green |
| | | 4 wt % | | | | |
| 4 | F | Ir(pdppy)₃- | Ba(acac)₂- | 53 cd/A | 147.0 | green |
| | | 15 wt % | 5 wt % | | | |
| 5 | F | Ir(ppy)₂(mdppy)- | — | 58 cd/A | 92.0 | green |
| | | 9 wt % | | | | |
| 6 | B | Ir(pdpiq)₃- | — | 8 cd/A | 61.0 | red |
| | | 8 wt % | | | | |
| 7 | M | Ir(mdpiq)₃- | — | 6 cd/A | 76.0 | red |
| | | 8 wt % | | | | |
| 8 | L | D- | — | 2 cd/A | 3.0 | blue |
| | | 1 wt % | | | | |
| 9 | B | Ir(pdpiq)₂(acac)- | — | 5 cd/A | 47.0 | red |
| | | 8 wt % | | | | |
| 10 | B | Ir(3dpoipt)₃- | — | 3 cd/A | 0.5 | blue |
| | | 11 wt % | | | | |
| 11 | F | Ir(ppy)₃- | — | 2 cd/A | 1.0 | green |
| | | N.D. | | | | |
| 12 | F | Ir(piq)₂(acac)- | — | 6 cd/A | 40.0 | red |
| | | 8 wt % | | | | |
| 13 | D | C545T- | — | 5 cd/A | 220.0 | green |
| | | 0.8 wt % | | | | |

For all of the organic EL elements using the guest materials including the ones other than iridium complex (Example 8 and 13) and the ones that do not have phosphine oxide moiety (Example 11 to 13), the current efficiencies and lifetimes comparable to or better than those observed in the organic EL element using Ir(ppy)₃ used as a phosphorescent dye in the organic EL elements (Example 11). Particularly, the organic EL element in which Ir(ppy)₂(pdppy) is used as the guest material (Example 1) shows the current efficiency η_{c} of 67 cd/A at maximum was observed. It may be attributable to inhibition of the aggregation of the guest molecule and the enhancement of its dispersibility in the emissive layer, therefore concentration quenching is suppressed and the carrier transfer efficiencies are improved.

The results showed that addition of metal compound such as Li(acac), Ba(acac)₂ enhances the durability of the emissive layer (See Examples 1, 2 and 3, 4).

### DESCRIPTION OF SYMBOLS

1: organic electroluminescent element
2: substrate
3: anode
4: hole injection layer
5: hole transport layer
6: emissive layer
7: cathode
8: sealant

1. An organic electroluminescent element having a plurality of laminated organic layers sandwiched between anode and cathode, wherein the plurality of laminated organic layers comprising;
a hole transport layer composed of organic compounds insoluble in alcohol solvent and;
an emissive layer formed by a wet process so that it contacts with the hole transport layer on the side facing with the cathode, wherein
the emissive layer contains host materials consisting of one or more phosphine oxide derivatives soluble in alcohol solvent and guest materials consisting of one or more organic compounds and/or organic metal compounds soluble in alcohol solvent which can be excited electrically by recombination of injected electrons and holes to emit light.

2. The organic electroluminescent element according to claim 1, wherein the guest material has one or more phosphine oxide moieties that do not coordinate to transition metal element or ion.

3. The organic electroluminescent element according to claim 1, wherein the emissive layer further comprises one or more metal salt or metal compounds of the metal with the electronegativity of 1.6 or less.

4. The organic electroluminescent element according to claim 1, wherein the phosphine oxide derivative constituting the host material is represented by the general Formula (1) shown below; 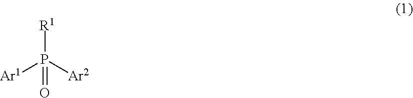
wherein
R¹ in Formula (1) is a group having one or more aryl and/or heteroaryl groups, which may have a phosphine oxide group represented by Formula (2) shown below on any carbon atoms;
Ar¹ and Ar² are aryl groups which may have one or more substituents independently of each other, where Ar¹ and Ar² may bind to form a heterocycle containing phosphorous atom; and; 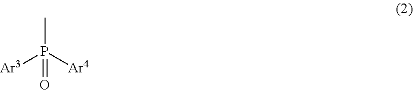
Ar³ and Ar⁴ in Formula (2) are aryl groups that may have one or more substituents independently of each other, where Ar³ and Ar⁴ may bind to form a heterocycle containing phosphorous atom.

5. The organic electroluminescent element according to claim 4, wherein the phosphine oxide derivatives represented by Formula (1) are one or more phosphine oxide derivatives selected from the group consisting of the compounds represented by the Formulae A to Q shown below.

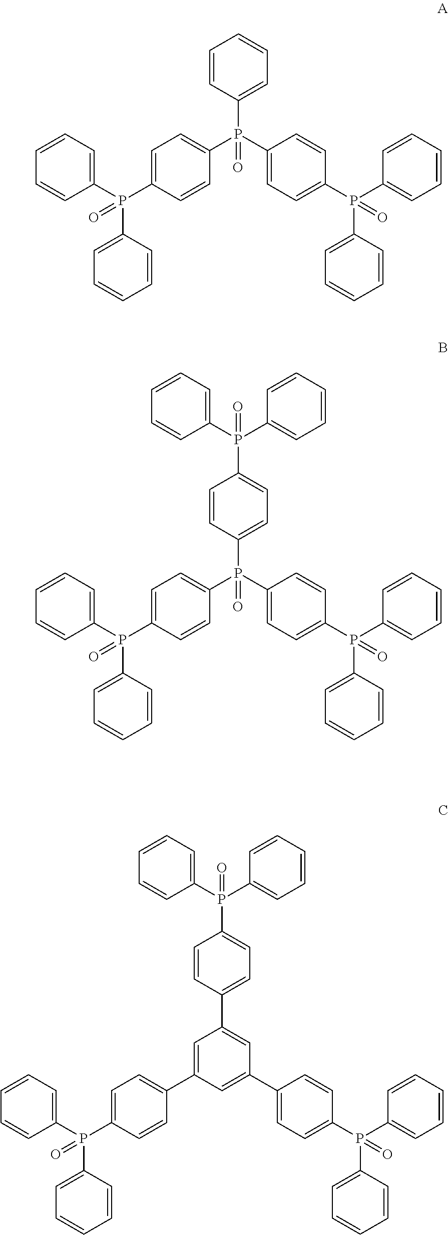

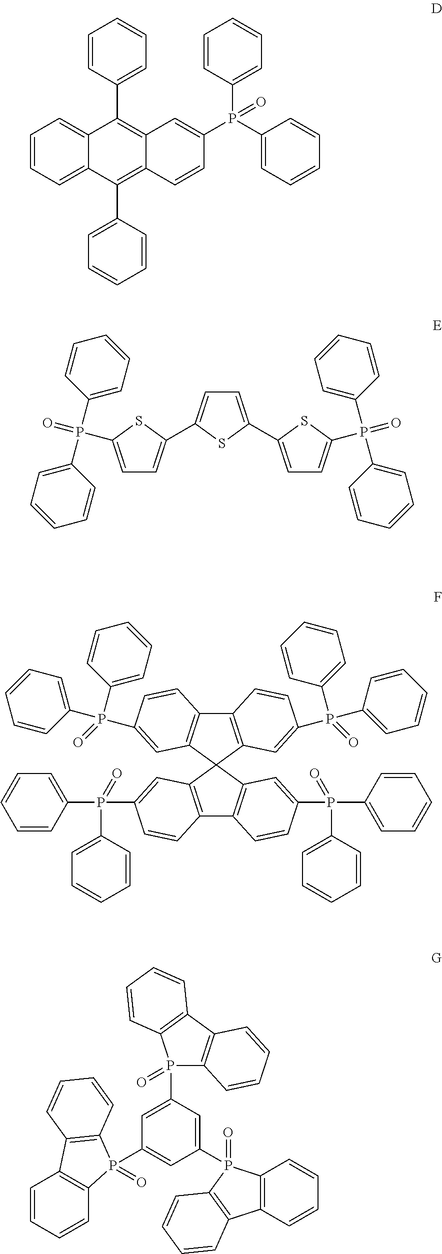

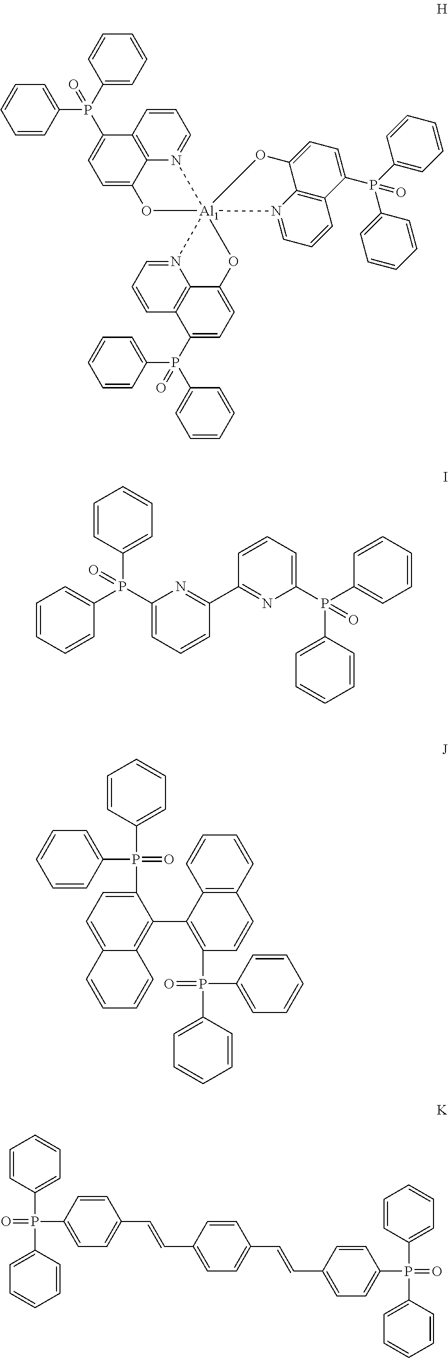

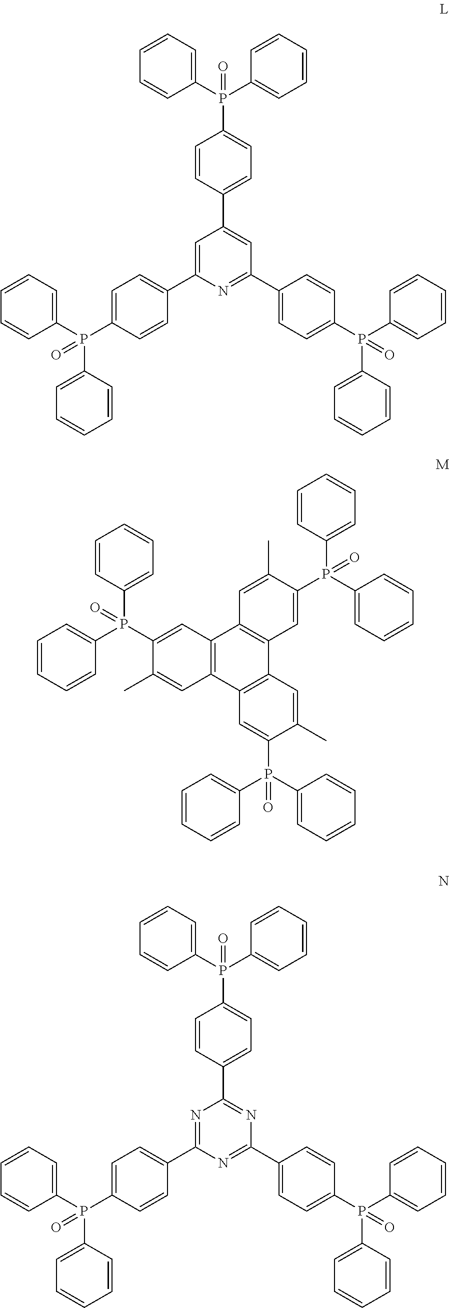

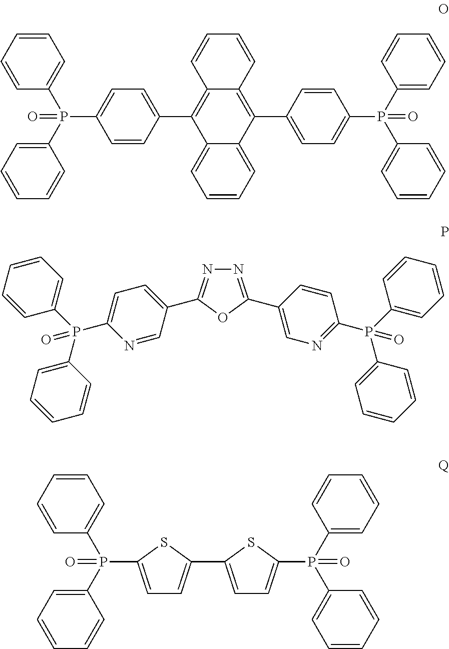

6. The organic electroluminescent element according to claim 1, wherein the organic compounds and/or organic metal compounds constituting the guest material are represented by general Formula (3) shown below: 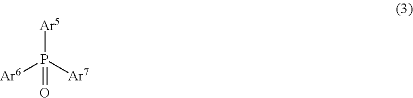
Ar⁵, Ar⁶ and Ar⁷ in Formula (3) are aryl or heteroaryl groups that may have one or more substituents independently of each other, and at least one of Ar⁵, Ar⁶ and Ar⁷ are luminescence aromatic moieties that can be excited electrically by recombination of injected electrons and holes to emit light.

7. The organic electroluminescent element according to claim 6, wherein the organic compounds and/or organic metal compounds represented by Formula (3) shown above are iridium complex represented by Formula (3)′ shown below; 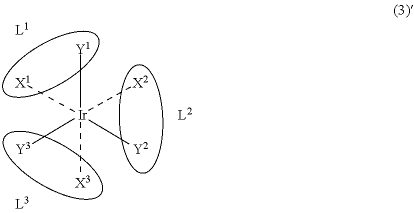
L¹, L² and L³ in Formula (3)′ are bidendate ligands, X¹ and Y¹, X² and Y², and X³ and Y³ are coordinating atoms of L¹, L² and L³, respectively selected from the group consisting of carbon, oxygen and nitrogen atoms and at least one of L¹, L² and L³ have phosphine oxide group represented by Formula (2) shown below; and 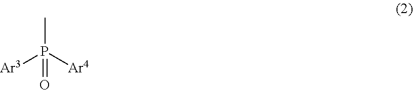
Ar³ and Ar⁴ in Formula (2) are aryl groups that may have one or more substituents independently of each other, where Ar³ and Ar⁴ may bind to form a heterocycle containing phosphorous atom.

8. The organic electroluminescent element according to claim 7, wherein the iridium complex represented by Formula (3)′ is the iridium complex represented by any one of Formula (4) to (15) shown below; 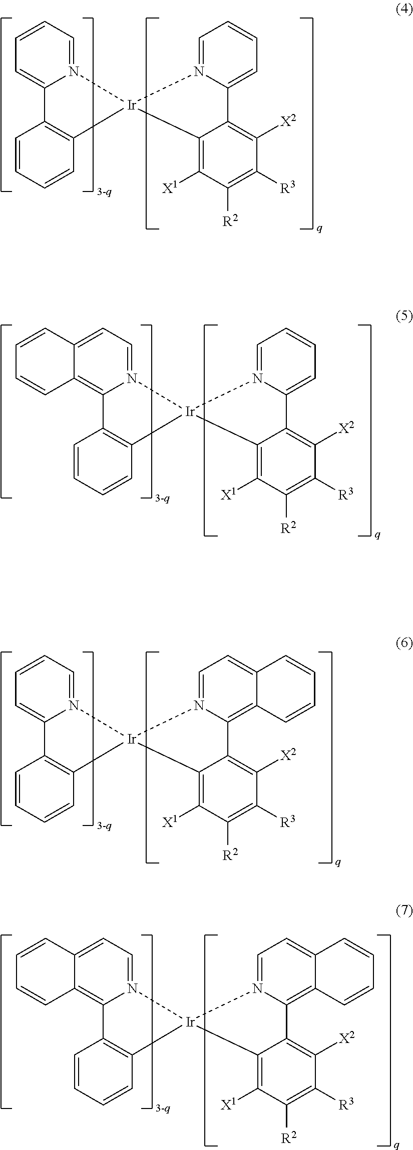 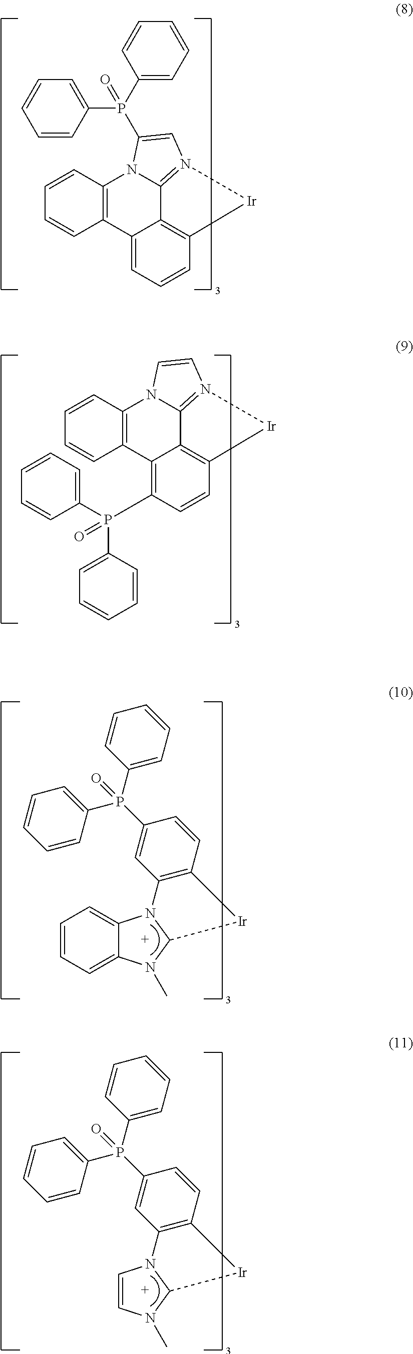 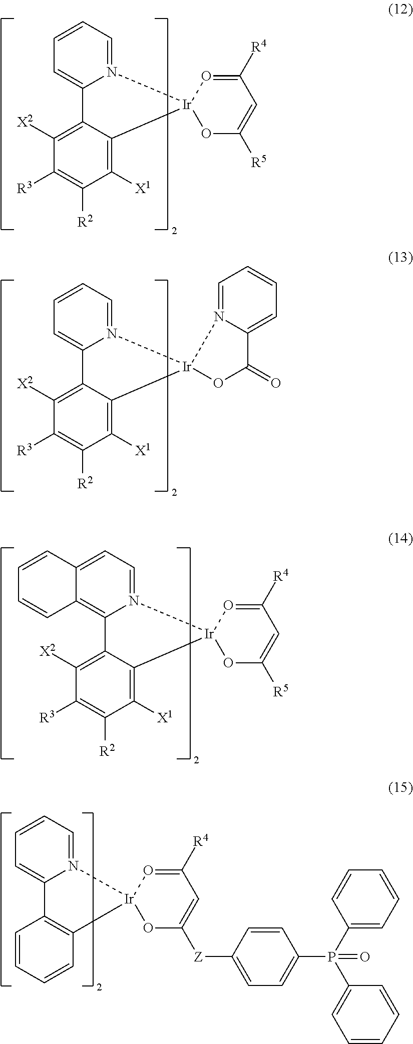
the one of R² and R³ in Formula (4) to (15) is hydrogen atom or phosphine oxide group represented by Formula (2) shown above, the other of R² and R³, X¹ and X² are selected from the group consisting of hydrogen and fluorine atoms independently of each other, q is an integer of 1, 2 or 3, R⁴ and R⁵ are groups selected from the group consisting of linear or branched alkyl groups having 1 to 12 carbon atoms, linear or branched fluoroalkyl groups having 1 to 12 carbon atoms, aryl groups and heteroaryl groups, and Z is direct bond or linear alkylene group having 1 to 12 carbon atoms.

9. The organic electroluminescent element according to claim 6, wherein the iridium complex represented by Formula (3)′ is the iridium complex represented by Formula (4)′ shown below: 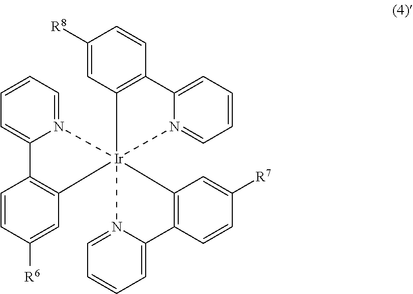
R⁶, R⁷ and R⁸ in Formula (4)′ are hydrogen atom or phosphine oxide group represented by Formula (2) shown above and at least one of R⁶, R⁷ and R⁸ are phosphine oxide group represented by Formula (2) shown above.

10. An alcohol-soluble phosphorescent material represented by Formula (3)′ shown below; 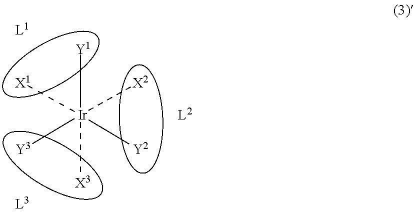
L¹, L² and L³ in Formula (3)′ are bidendate ligands, X¹ and Y¹, X² and Y², and X³ and Y³ are coordinating atoms of L¹, L² and L³, respectively selected from the group consisting of carbon, oxygen and nitrogen atoms and at least one of L¹, L² and L³ have phosphine oxide group represented by Formula (2) shown below; and 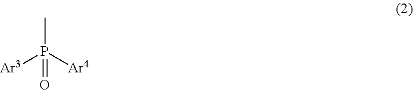
Ar³ and Ar⁴ in Formula (2) are aryl groups that may have one or more substituents independently of each other, where Ar³ and Ar⁴ may bind to form a heterocycle containing phosphorous atom.

11. The alcohol-soluble phosphorescent material according to claim 10, wherein the iridium complex represented by Formula (3)′ is the iridium complex represented by any one of Formula (4) to (15) shown below; 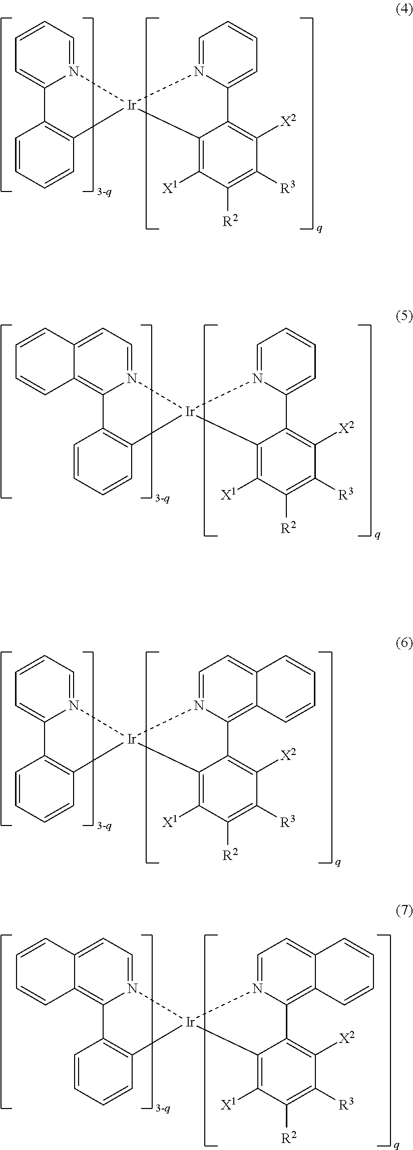 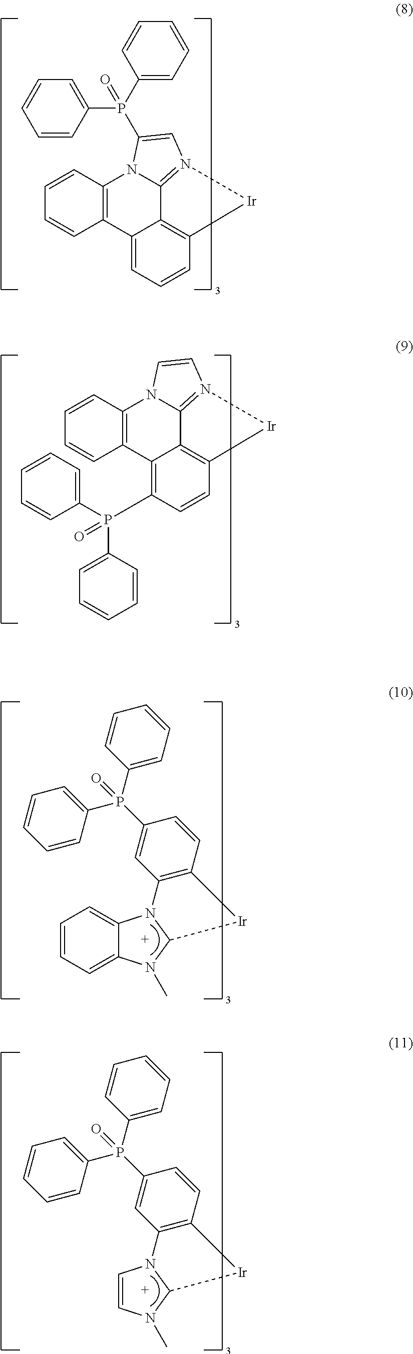 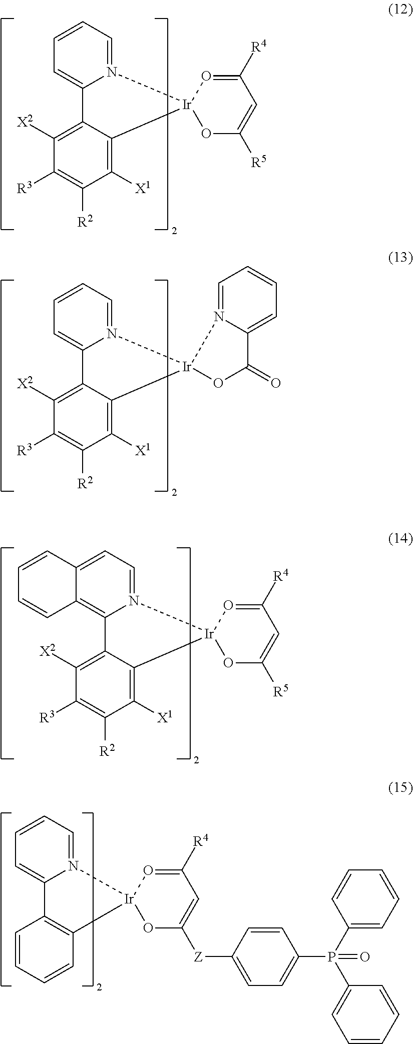
the one of R² and R³ in Formula (4) to (15) is hydrogen atom or phosphine oxide group represented by Formula (2) shown below, the other of R² and R³, X¹ and X² are selected from the group consisting of hydrogen and fluorine atoms independently of each other, q is an integer of 1, 2 or 3, R⁴ and R⁵ are groups selected from the group consisting of linear or branched alkyl groups having 1 to 12 carbon atoms, linear or branched fluoroalkyl groups having 1 to 12 carbon atoms, aryl groups and heteroaryl groups, and Z is direct bond or linear alkylene group having 1 to 12 carbon atoms. 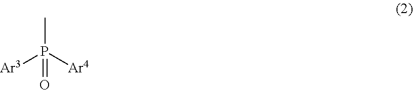
Ar³ and Ar⁴ in Formula (2) are aryl groups that may have one or more substituents independently of each other, where Ar³ and Ar⁴ may bind to form a heterocycle containing phosphorous atom.

12. The alcohol-soluble phosphorescent material according to claim 10, wherein the iridium complex represented by Formula (3)′ is the iridium complex represented by Formula (4)′ shown below; 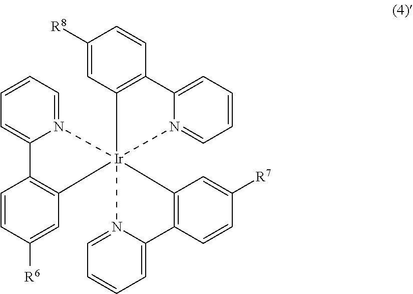
R⁶, R⁷ and R⁸ in Formula (4)′ are hydrogen atom or phosphine oxide group represented by Formula (2) shown above and at least one of R⁶, R⁷ and R⁸ are phosphine oxide group represented by Formula (2) shown above.
